(19) United States
(12) Patent Application Publication
(10) Pub. No.: US 2009/0032490 A1
(43) Pub. Date: Feb. 5, 2009

(54) METHOD OF FABRICATING COLOR FILTER

(75) Inventors: Huai-Hsuan Tsai, Tainan City (TW); Fu-Kuo Ou, Hsinchu City (TW)

Correspondence Address: J C PATENTS, INC., 4 VENTURE, SUITE 250, IRVINE, CA, 92618, US

(73) Assignees: UNITED MICROELECTRONICS CORP., Hsinchu (TW); UNITED MICRODISPLAY OPTRONICS CORP., Hsin-Chu City, (TW)

(21) Appl. No.: 11/832,808

(22) Filed: Aug. 2, 2007

(51) Int. Cl. G03F 1/00

(52) U.S. Cl. 216/12

(57) ABSTRACT

Methods for fabricating color filters are provided. Firstly, a substrate having a first region and a second region is provided. Then, a first dichroic layer and a first mask layer are formed on the first region sequentially. Next, a second dichroic layer is formed on the substrate to cover the first mask layer and the surface of the second region of the substrate. Thereafter, a second mask layer is formed on the second dichroic layer on the second region. Afterwards, the second dichroic layer on the first region and between the first mask layer and the second mask layer is etched. Then, the first mask layer and the second mask layer are removed.

### BACKGROUND OF THE INVENTION

1. Field of the Invention

The present invention relates to a method of fabricating a filter. More particularly, the present invention relates to a method of fabricating a color filter.

2. Description of Related Art

Color filters are capable of filtering light emitted by light sources, and are indispensable components in many display elements. For example, liquid crystal displays (LCD) and complementary metal oxide semiconductor (CMOS) image sensors (CIS) use the color filters to achieve color display effects. Usually, a color filter is formed by alternating dichroic layers of different refractive indexes, so as to filter the light of certain wavelengths.

A conventional method of fabricating a color filter usually involves the following steps. Firstly, a patterned photoresist layer is formed on a substrate. Then, dichroic layers of different refractive indexes are formed on the patterned photoresist layer and the substrate. Afterwards, a lift-off process is used to remove the dichroic layers covered on the photoresist layer while removing the photoresist, so as to realize the purpose of patterning.

However, referring to FIG. 1, according to the above method, after a first dichroic layer 108, a second dichroic layer 112, and a third dichroic layer 120 are formed on a first region 102, a second region 104, and a third region 106 of a substrate 100 respectively, edge protrusions 130 will be left at the edges of the second dichroic layer 112 and the third dichroic layer 120 as the lift-off process is used, which will influence the performance of filter severely.

### SUMMARY OF THE INVENTION

Accordingly, the present invention is directed to a method of fabricating a color filter, which prevents edge protrusions being left on formed patterned dichroic layers, so as to improve filtering performance.

The present invention provides a method of fabricating a color filter. Firstly, a substrate having a first region and a second region is provided. Then, a first dichroic layer and a first mask layer are formed on the first region sequentially. Next, a second dichroic layer is formed on the substrate to cover the first mask layer and the surface of the second region of the substrate. Thereafter, a second mask layer is formed on the second dichroic layer on the second region. Afterwards, the second dichroic layer on the first region and between the first mask layer and the second mask layer is etched. Then, the first mask layer and the second mask layer are removed.

In the method of fabricating a color filter according to an embodiment of the present invention, the first mask layer includes a photoresist layer.

In the method of fabricating a color filter according to an embodiment of the present invention, the second mask layer includes an organic material layer or a buffer layer.

In the method of fabricating a color filter according to an embodiment of the present invention, the first dichroic layer and the second dichroic layer are stacked layers selected from a group consisting of TiO₂, Ta₂O₅, SiO₂, RuₓO_{y}, ZnS, and MgF₂.

In the method of fabricating a color filter according to an embodiment of the present invention, the substrate further includes a third region, such that the first region is located between the second region and the third region, and the method further includes forming a third mask layer on the first dichroic layer and the second dichroic layer. Next, a third dichroic layer is formed on the substrate to cover the third mask layer and the surface of the third region of the substrate. Thereafter, a fourth mask layer is formed on the third dichroic layer on the third region. Afterwards, the third dichoric layer is etched back, so as to remove the third dichroic layer on the third mask layer and between the third mask layer and the fourth mask layer. Then, the third and the fourth mask layers are removed.

In the method of fabricating a color filter according to an embodiment of the present invention, the third mask layer includes a photoresist layer.

In the method of fabricating a color filter according to an embodiment of the present invention, the fourth mask layer includes an organic material layer or a buffer layer.

In the method of fabricating a color filter according to an embodiment of the present invention, the third dichroic layer is a stacked layer selected from a group consisting of TiO₂, Ta₂O₅, SiO₂, RuₓO_{y}, ZnS, and MgF₂.

In the method of fabricating a color filter according to an embodiment of the present invention, the substrate further includes a third region, such that the first region is located between the second region and the third region, and the method further includes forming an inter layer on the first dichroic layer and the second dichroic layer sequentially. Next, a third dichroic layer is formed on the substrate to cover the inter layer and the surface of the third region of the substrate. Thereafter, a third mask layer is formed on the third dichroic layer on the third region. Afterwards, the third dichoric layer is etched back, so as to remove the third dichroic layer on the inter layer and between the third mask layer and the inter layer. Then, the third mask layer and the inter layer are removed.

In the method of fabricating a color filter according to an embodiment of the present invention, the third mask layer includes an organic material layer or a buffer layer.

In the method of fabricating a color filter according to an embodiment of the present invention, the material of the inter layer includes silicon oxide or spin on glass.

In the method of fabricating a color filter according to an embodiment of the present invention, the third dichroic layer is a stacked layer selected from a group consisting of TiO₂, Ta₂O₅, SiO₂, RuₓO_{y}, ZnS, and MgF₂.

In the method of fabricating a color filter according to an embodiment of the present invention, the substrate further includes a third region, such that the first region is located between the second region and the third region, and the method further includes forming a third mask layer on the first dichroic layer and the second dichroic layer. Next, a third dichroic layer is formed on the substrate to cover the third mask layer and the surface of the third region of the substrate. Then, a lift-off process is performed to remove the third mask layer and the dichroic layer thereon, and leaves the third dichroic layer on the third region and an edge protrusion. Then, a fourth mask layer is formed on the first, the second, and the third dichroic layers to expose the edge protrusion. Afterwards, the edge protrusion is etched away using the fourth mask layer as a mask. Then, the fourth mask layer is removed.

In the method of fabricating a color filter according to an embodiment of the present invention, the third mask layer includes a photoresist layer.

In the method of fabricating a color filter according to an embodiment of the present invention, the fourth mask layer includes an organic material layer or a buffer layer.

In the method of fabricating a color filter according to an embodiment of the present invention, the third dichroic layer is a stacked layer selected from a group consisting of TiO₂, Ta₂O₅, SiO₂, RuₓO_{y}, ZnS, and MgF₂.

In the method of fabricating a color filter according to an embodiment of the present invention, the substrate further includes a third region, such that the first region is located between the second region and the third region, and the method further includes forming an inter layer and a third mask layer on the first dichroic layer and the second dichroic layer sequentially. Next, a third dichroic layer is formed on the substrate to cover the third mask layer and the surface of the third region of the substrate. Then, a lift-off process is performed to remove the third mask layer and the third dichroic layer thereon, and leaves the third dichroic layer and an edge protrusion on the third region. Then, a fourth mask layer is formed on the third dichroic layer to expose the edge protrusion. Afterwards, the edge protrusion is etched away using the fourth mask layer and the inter layer as a mask. Then, the fourth mask layer and the inter layer are removed.

In the method of fabricating a color filter according to an embodiment of the present invention, the third mask layer includes a photoresist layer.

In the method of fabricating a color filter according to an embodiment of the present invention, the fourth mask layer includes an organic material layer or a buffer layer.

In the method of fabricating a color filter according to an embodiment of the present invention, the material of the inter layer includes silicon oxide or spin on glass.

In the method of fabricating a color filter according to an embodiment of the present invention, the third dichroic layer is a stacked layer selected from a group consisting of TiO₂, Ta₂O₅, SiO₂, RuₓO_{y}, ZnS, and MgF₂.

The present invention provides a method of fabricating a color filter. Firstly, a substrate having a first region and a second region is provided. Then, a first dichroic layer and a first inter layer are formed on the first region sequentially. Then, a second dichroic layer is formed on the substrate. Thereafter, a first mask layer is formed on the second dichroic layer on the second region. Next, the second dichroic film on the first region and between the first inter layer and the first mask layer are etched using the first mask layer as an etching mask. Then, the first inter layer and the first mask layer are removed.

In the method of fabricating a color filter according to an embodiment of the present invention, the material of the first inter layer includes silicon oxide or spin on glass.

In the method of fabricating a color filter according to an embodiment of the present invention, the first mask layer includes an organic material layer or a buffer layer.

In the method of fabricating a color filter according to an embodiment of the present invention, the first dichroic layer and the second dichroic layer are stacked layers selected from a group consisting of TiO₂, Ta₂O₅, SiO₂, RuₓO_{y}, ZnS, and MgF₂.

In the method of fabricating a color filter according to an embodiment of the present invention, the substrate further includes a third region, such that the first region is located between the second region and the third region, and the method further includes forming a second mask layer on the first dichroic layer and the second dichroic layer. Next, a third dichroic layer is formed on the substrate to cover the second mask layer and the surface of the third region of the substrate. Thereafter, a third mask layer is formed on the third dichroic layer on the third region. Afterwards, the third dichoric layer is etched back, so as to remove the third dichroic layer on the second mask layer and between the first inter layer and the third mask layer. Then, the second and the third mask layers and the first inter layer are removed.

In the method of fabricating a color filter according to an embodiment of the present invention, the second mask layer includes a photoresist layer.

In the method of fabricating a color filter according to an embodiment of the present invention, the third mask layer includes an organic material layer or a buffer layer.

In the method of fabricating a color filter according to an embodiment of the present invention, the third dichroic layer is a stacked layer selected from a group consisting of TiO₂, Ta₂O₅, SiO₂, RuₓO_{y}, ZnS, and MgF₂.

In the method of fabricating a color filter according to an embodiment of the present invention, the substrate further includes a third region, such that the first region is located between the second region and the third region, and the method further includes forming a second inter layer on the second dichroic layer, and forming a third dichroic layer on the substrate, so as to cover the first and the second inter layers and the surface of the third region of the substrate. Thereafter, a second mask layer is formed on the third dichroic layer on the third region. Afterwards, the third dichoric layer is etched back, so as to remove the third dichroic layer on the first and the second inter layers and between the second mask layer and the first inter layer. Then, the second mask layer and the first and the second inter layers are removed.

In the method of fabricating a color filter according to an embodiment of the present invention, the material of the second inter layer includes silicon oxide or spin on glass.

In the method of fabricating a color filter according to an embodiment of the present invention, the second mask layer includes an organic material layer or a buffer layer.

In the method of fabricating a color filter according to an embodiment of the present invention, the third dichroic layer is a stacked layer selected from a group consisting of TiO₂, Ta₂O₅, SiO₂, RuₓO_{y}, ZnS, and MgF₂.

In the method of fabricating a color filter according to an embodiment of the present invention, the substrate further includes a third region, such that the first region is located between the second region and the third region, and the method further includes forming a second mask layer over the first and the second regions. Next, a third dichroic layer is formed on the substrate to cover the second mask layer and the surface of the third region of the substrate. Then, a lift-off process is performed to remove the second mask layer and the first dichroic layer thereon, and leaves the third dichroic layer on the third region and an edge protrusion. Then, a third mask layer is formed on the second and the third dichroic layers to expose the edge protrusion. Afterwards, the edge protrusion is etched away using the third mask layer and the first inter layer as a mask. Then, the third mask layer and the first inter layer are removed.

In the method of fabricating a color filter according to an embodiment of the present invention, the second mask layer includes a photoresist layer.

In the method of fabricating a color filter according to an embodiment of the present invention, the third mask layer includes an organic material layer or a buffer layer.

In the method of fabricating a color filter according to an embodiment of the present invention, the third dichroic layer is a stacked layer selected from a group consisting of TiO₂, Ta₂O₅, SiO₂, RuₓO_{y}, ZnS, and MgF₂.

In the method of fabricating a color filter according to an embodiment of the present invention, the substrate further includes a third region, such that the first region is located between the second region and the third region, and the method further includes forming a second inter layer on the second dichroic layer. Then, a second mask layer is formed on the first inter layer and the second inter layer. Next, a third dichroic layer is formed on the substrate to cover the second mask layer and the surface of the third region of the substrate. Then, a lift-off process is performed to remove the second mask layer and the third dichroic layer thereon, and leaves the third dichroic layer on the third region and an edge protrusion. Then, a third mask layer is formed on the third dichroic layer to expose the edge protrusion. Afterwards, the edge protrusion is etched away using the third mask layer and the first and the second inter layers as a mask. Then, the third mask layer and the first and the second inter layers are removed.

In the method of fabricating a color filter according to an embodiment of the present invention, the material of the second inter layer includes silicon oxide or spin on glass.

In the method of fabricating a color filter according to an embodiment of the present invention, the second mask layer includes a photoresist layer.

In the method of fabricating a color filter according to an embodiment of the present invention, the third mask layer includes an organic material layer or a buffer layer.

In the method of fabricating a color filter according to an embodiment of the present invention, the third dichroic layer is a stacked layer selected from a group consisting of TiO₂, Ta₂O₅, SiO₂, RuₓO_{y}, ZnS, and MgF₂.

The present invention provides a method of fabricating a color filter. Firstly, a substrate having a first region and a second region is provided. Then, a first dichroic layer and a first mask layer are formed on the first region of the substrate sequentially. Next, a second dichroic layer is formed on the substrate to cover the first mask layer and the surface of the second region of the substrate. Then, a first lift-off process is performed to remove the first mask layer and the first dichroic layer thereon, and leaves the second dichroic layer on the second region and an edge protrusion. Next, a second mask layer is formed on the substrate to cover the second region. Afterwards, an edge protrusion is etched away. Then, the second mask layer is removed.

In the method of fabricating a color filter according to an embodiment of the present invention, the first mask layer includes a photoresist layer.

In the method of fabricating a color filter according to an embodiment of the present invention, the second mask layer includes an organic material layer or a buffer layer.

In the method of fabricating a color filter according to an embodiment of the present invention, the first and the second dichroic layers are stacked layers selected from a group consisting of TiO₂, Ta₂O₅, SiO₂, RuₓO_{y}, ZnS, and MgF₂.

In the method of fabricating a color filter according to an embodiment of the present invention, the substrate further includes a third region, such that the first region is disposed in the second region and the third region. After the first lift-off process, the method further includes forming the second mask layer on the substrate to cover the second dichroic layer on the second region and the first dichroic layer on the first region. Next, a third dichroic layer is formed on the substrate to cover the second mask layer and the surface of the third region of the substrate. Thereafter, a third mask layer is formed on the third dichroic layer on the third region. Afterwards, the third dichoric layer is etched back, so as to remove the third dichroic layer on the second mask layer and between the second mask layer and the third mask layer and to remove a first edge protrusion at the same time. Then, the second mask layer is removed, and the third mask layer is removed at the same time.

In the method of fabricating a color filter according to an embodiment of the present invention, the second mask layer includes a photoresist layer.

In the method of fabricating a color filter according to an embodiment of the present invention, the third mask layer includes an organic material layer or a buffer layer.

In the method of fabricating a color filter according to an embodiment of the present invention, the third dichroic layer is a stacked layer selected from a group consisting of TiO₂, Ta₂O₅, SiO₂, RuₓO_{y}, ZnS, and MgF₂.

In the method of fabricating a color filter according to an embodiment of the present invention, the substrate further includes a third region, such that the first region is located between the second region and the third region. The first mask layer further covers the surface of the third region of the substrate. After the first lift-off process, the method further includes forming an inter layer on the substrate. Next, a second mask layer is formed on the substrate to cover the second region and further cover the first region. Then, the inter layer not covered by the second mask layer is etched away. Then, the second mask layer is removed. Next, a third dichroic layer is formed on the substrate to cover the inter layer and the surface of the third region of the substrate. Thereafter, a third mask layer is formed on the third dichroic layer on the third region. Afterwards, the third dichoric layer is etched back, so as to remove the third dichroic layer on the inter layer and between the third mask layer and the inter layer and to remove the first edge protrusion. Then, the third mask layer and the inter layer are removed.

In the method of fabricating a color filter according to an embodiment of the present invention, the material of the inter layer includes silicon oxide or spin on glass.

In the method of fabricating a color filter according to an embodiment of the present invention, the third mask layer includes an organic material layer or a buffer layer.

In the method of fabricating a color filter according to an embodiment of the present invention, the third dichroic layer is a stacked layer selected from a group consisting of TiO₂, Ta₂O₅, SiO₂, RuₓO_{y}, ZnS, and MgF₂.

In the method of fabricating a color filter according to an embodiment of the present invention, the substrate further includes a third region, such that the first region is located between the second region and the third region. The first mask layer further covers the surface of the third region of the substrate. After the first lift-off process, the method further includes forming a second mask layer on the substrate to cover the second region and further cover the first region. Next, a third dichroic layer is formed on the substrate to cover the second mask layer and the surface of the third region of the substrate. Then, a second lift-off process is performed to remove the second mask layer and the third dichroic layer thereon, and leaves the third dichroic layer on the third region and a second edge protrusion. Then, a third mask layer is formed on the first, the second, and the third dichroic layers to expose the first and the second edge protrusions. Afterwards, the first and the second edge protrusions are etched away using the third mask layer is used as a mask. Then, the third mask layer is removed.

In the method of fabricating a color filter according to an embodiment of the present invention, the second mask layer includes a photoresist layer.

In the method of fabricating a color filter according to an embodiment of the present invention, the third mask layer includes an organic material layer or a buffer layer.

In the method of fabricating a color filter according to an embodiment of the present invention, the third dichroic layer is a stacked layer selected from a group consisting of TiO₂, Ta₂O₅, SiO₂, RuₓO_{y}, ZnS, and MgF₂.

In the method of fabricating a color filter according to an embodiment of the present invention, the substrate further includes a third region, such that the first region is located between the second region and the third region. The first mask layer further covers the surface of the third region of the substrate. After the first lift-off process, the method further includes forming an inter layer on the first dichroic layer and the second dichroic layer. Then, a second mask layer is formed on the substrate to cover the second region and the first region. Next, a third dichroic layer is formed on the substrate to cover the second mask layer and the surface of the third region of the substrate. Then, a second lift-off process is performed to remove the second mask layer and the third dichroic layer thereon, and leaves the third dichroic layer and a second edge protrusion on the third region. Then, a third mask layer is formed on the third dichroic layer to expose the second edge protrusion. Afterwards, the first and the second edge protrusions are etched away using the third mask layer as a mask. Then, the third mask layer and the inter layer are removed.

In the method of fabricating a color filter according to an embodiment of the present invention, the material of the inter layer includes silicon oxide or spin on glass.

In the method of fabricating a color filter according to an embodiment of the present invention, the second mask layer includes a photoresist layer.

In the method of fabricating a color filter according to an embodiment of the present invention, the third mask layer includes an organic material layer or a buffer layer.

In the method of fabricating a color filter according to an embodiment of the present invention, the third dichroic layer is a stacked layer selected from a group consisting of TiO₂, Ta₂O₅, SiO₂, RuₓO_{y}, ZnS, and MgF₂.

The present invention provides a method of fabricating a color filter. Firstly, a substrate having a first region and a second region is provided. Then, a first dichroic layer, a first inter layer, and a first mask layer are formed on the first region of the substrate sequentially. Then, a second dichroic layer is formed on the substrate. Then, a first lift-off process is performed to remove the first mask layer and the first dichroic layer thereon, and leaves the second dichroic layer on the second region and a first edge protrusion. Next, a second mask layer is formed on the substrate to cover the second region. Afterwards, the first edge protrusion is etched away using the second mask layer and the first inter layer as a mask. Then, the first inter layer and the second mask layer are removed.

In the method of fabricating a color filter according to an embodiment of the present invention, the material of the first inter layer includes silicon oxide or spin on glass.

In the method of fabricating a color filter according to an embodiment of the present invention, the first mask layer includes a photoresist layer.

In the method of fabricating a color filter according to an embodiment of the present invention, the second mask layer includes an organic material layer or a buffer layer.

In the method of fabricating a color filter according to an embodiment of the present invention, the first and the second dichroic layers are stacked layers selected from a group consisting of TiO₂, Ta₂O₅, SiO₂, RuₓO_{y}, ZnS, and MgF₂.

In the method of fabricating a color filter according to an embodiment of the present invention, the substrate further includes a third region, such that the first region is located between the second region and the third region. The first mask layer further covers the surface of the third region of the substrate. After forming the second mask layer, the method further includes forming a third dichroic layer on the substrate to cover the second mask layer and the surface of the third region of the substrate. Thereafter, a third mask layer is formed on the third dichroic layer on the third region. Afterwards, the third dichoric layer is etched back, so as to remove the third dichroic layer on the second mask layer and between the first inter layer and the third mask layer and to remove a first edge protrusion. Then, the second and the third mask layers and the first inter layer are removed.

In the method of fabricating a color filter according to an embodiment of the present invention, the mask layer includes an organic material layer or a buffer layer.

In the method of fabricating a color filter according to an embodiment of the present invention, the third dichroic layer is a stacked layer selected from a group consisting of TiO₂, Ta₂O₅, SiO₂, RuₓO_{y}, ZnS, and MgF₂.

In the method of fabricating a color filter according to an embodiment of the present invention, the substrate further includes a third region, such that the first region is located between the second region and the third region. The first mask layer further covers the surface of the third region of the substrate. After the first lift-off process, the method further includes forming a second inter layer on the substrate. Next, a second mask layer is formed on the substrate to cover the second region and further cover the first region. Then, the second inter layer not covered by the second mask layer is etched away. Then, the second mask layer is removed. Next, a third dichroic layer is formed on the substrate to cover the second inter layer and the surface of the third region of the substrate. Thereafter, a third mask layer is formed on the third dichroic layer on the third region. Afterwards, the third dichoric layer is etched back, so as to remove the third dichroic layer on the second inter layer and between the first inter layer and the third mask layer and to remove the first edge protrusion. Then, the third mask layer and the first and the second inter layers are removed.

In the method of fabricating a color filter according to an embodiment of the present invention, the material of the second inter layer includes silicon oxide or spin on glass.

In the method of fabricating a color filter according to an embodiment of the present invention, the third mask layer includes an organic material layer or a buffer layer.

In the method of fabricating a color filter according to an embodiment of the present invention, the third dichroic layer is a stacked layer selected from a group consisting of TiO₂, Ta₂O₅, SiO₂, RuₓO_{y}, ZnS, and MgF₂.

In the method of fabricating a color filter according to an embodiment of the present invention, the substrate further includes a third region, such that the first region is located between the second region and the third region. The first mask layer further covers the surface of the third region of the substrate. After the first lift-off process, the method further includes forming a second mask layer on the substrate to cover the second region and further cover the first region. Next, a third dichroic layer is formed on the substrate to cover the second mask layer and the surface of the third region of the substrate. Then, a second lift-off process is performed to remove the second mask layer and the third dichroic layer thereon, and leaves the third dichroic layer and a second edge protrusion on the third region. Then, a third mask layer is formed on the second and the third regions to expose the first and the second edge protrusions. Afterwards, the first and the second edge protrusions are etched away using the second mask layer and the first inter layer as a mask. Then, the third mask layer and the first inter layer are removed.

In the method of fabricating a color filter according to an embodiment of the present invention, the second mask layer includes a photoresist layer.

In the method of fabricating a color filter according to an embodiment of the present invention, the third mask layer includes an organic material layer or a buffer layer.

In the method of fabricating a color filter according to an embodiment of the present invention, the third dichroic layer is a stacked layer selected from a group consisting of TiO₂, Ta₂O₅, SiO₂, RuₓO_{y}, ZnS, and MgF₂.

In the method of fabricating a color filter according to an embodiment of the present invention, the substrate further includes a third region, such that the first region is located between the second region and the third region. The first mask layer further covers the surface of the third region of the substrate. After the first lift-off process, the method further includes forming a second inter layer on the second dichroic layer. Next, a second mask layer is formed on the substrate to cover the second region and further cover the first region. Next, a third dichroic layer is formed on the substrate to cover the second mask layer and the surface of the third region of the substrate. Then, a second lift-off process is performed to remove the second mask layer and the third dichroic layer thereon, and leaves the third dichroic layer on the third region and a second edge protrusion. Then, a third mask layer is formed on the third region to expose the second edge protrusion. Afterwards, the first and the second edge protrusions are etched away using the third mask layer and the first and the second inter layers as a mask. Then, the third mask layer and the first and the second inter layers are removed.

In the method of fabricating a color filter according to an embodiment of the present invention, the material of the second inter layer includes silicon oxide or spin on glass.

In the method of fabricating a color filter according to an embodiment of the present invention, the second mask layer includes a photoresist layer.

In the method of fabricating a color filter according to an embodiment of the present invention, the third mask layer includes an organic material layer or a buffer layer.

In the method of fabricating a color filter according to an embodiment of the present invention, the third dichroic layer is a stacked layer selected from a group consisting of TiO₂, Ta₂O₅, SiO₂, RuₓO_{y}, ZnS, and MgF₂.

The method of fabricating a color filter of the present invention prevents edge protrusions being left on formed patterned dichroic layers, so as to improve filtering performance.

In order to make the aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic sectional view of a conventional method of fabricating a tricolor color filter.

FIGS. 2A-2E are sectional views of the processes of a method of fabricating a dichroic color filter according to the first embodiment of the present invention.

FIGS. 3A-1 to 3E-1 are sectional views of the processes of a method of fabricating a tricolor color filter according to the second embodiment of the present invention.

FIGS. 3A-2 to 3G-2 are sectional views of the processes of a method of fabricating a tricolor color filter according to the third embodiment of the present invention.

FIGS. 3A-3 to 3F-3 are sectional views of the processes of a method of fabricating a tricolor color filter according to the fourth embodiment of the present invention.

FIGS. 3A-4 to 3G-4 are sectional views of the processes of a method of fabricating a tricolor color filter according to the fifth embodiment of the present invention.

FIGS. 4A-4E are sectional views of the processes of a method of fabricating a dichroic color filter according to the sixth embodiment of the present invention.

FIGS. 5A-1 to 5G-1 are sectional views of the processes of a method of fabricating a tricolor color filter according to the seventh embodiment of the present invention.

FIGS. 5A-2 to 5H-2 are sectional views of the processes of a method of fabricating a tricolor color filter according to the eighth embodiment of the present invention.

FIGS. 5A-3 to 5G-3 are sectional views of the processes of a method of fabricating a tricolor color filter according to the ninth embodiment of the present invention.

FIGS. 5A-4 to 5H-4 are sectional views of the processes of a method of fabricating a tricolor color filter according to the tenth embodiment of the present invention.

FIGS. 6A-6E are sectional views of the processes of a method of fabricating a dichroic color filter according to the eleventh embodiment of the present invention.

FIGS. 7A-1 to 7E-1 are sectional views of the processes of a method of fabricating a tricolor color filter according to the twelfth embodiment of the present invention.

FIGS. 7A-2 to 7F-2 are sectional views of the processes of a method of fabricating a tricolor color filter according to the thirteenth embodiment of the present invention.

FIGS. 7A-3 to 7F-3 are sectional views of the processes of a method of fabricating a tricolor color filter according to the fourteenth embodiment of the present invention.

FIGS. 7A-4 to 7G-4 are sectional views of the processes of a method of fabricating a tricolor color filter according to the fifteenth embodiment of the present invention.

FIGS. 8A-8E are sectional views of the processes of a method of fabricating a dichroic color filter according to the sixteenth embodiment of the present invention.

FIGS. 9A-1 to 9E-1 are sectional views of the processes of a method of fabricating a tricolor color filter according to the seventeenth embodiment of the present invention.

FIGS. 9A-2 to 9F-2 are sectional views of the processes of a method of fabricating a tricolor color filter according to the eighteenth embodiment of the present invention.

FIGS. 9A-3 to 9F-3 are sectional views of the processes of a method of fabricating a tricolor color filter according to the nineteenth embodiment of the present invention.

FIGS. 9A-4 to 9G-4 are sectional views of the processes of a method of fabricating a tricolor color filter according to the twentieth embodiment of the present invention.

### DESCRIPTION OF EMBODIMENTS

Color filters of the present invention can be used to fabricate infrared filters, ultraviolet filters, RGB color filters, or CYM color filters. Only the RGB color filters are described for illustration, but they are not intended to limit the present invention.

In the embodiments below, the dichroic layer can be one selected from among red film, green film, or blue film. The dichroic layer can be a single layer formed by physical vapor deposition or chemical vapor deposition, or a multilayer formed by alternating film layers of different refractive indexes. For example, the single layer is an inorganic film layer, such as a silicon nitride layer, a silicon oxynitride layer, or an amorphous silicon layer. For example, the multilayer is formed by stacking a plurality of inorganic material layers. For example, the multilayer is formed by repeatedly forming each film on a substrate in the ascending order of refractive index. Or in another embodiment, the multilayer can also be formed by repeatedly forming each film on a substrate in the descending order of refractive index. The multilayer, for example, is a stacked layer selected from a group consisting of TiO₂, Ta₂O₅, SiO₂, RuₓO_{y} ZnS, and MgF₂. For example, the multilayer is a stacked layer formed by alternating a TiO₂ layer and a SiO₂ layer, alternating a Ta₂O₅ layer and an SiO₂ layer, or alternating a ZnS layer and an MgF₂ layer.

In the embodiments, the process of etch back or etching the dichroic films and edge protrusions employs, for example, chlorofluorocarbon or a gas mixture of carbon fluoride and chlorine is used as an etching gas. However, the process is not limited to the above description, and other known methods can also be applied.

### The First Embodiment

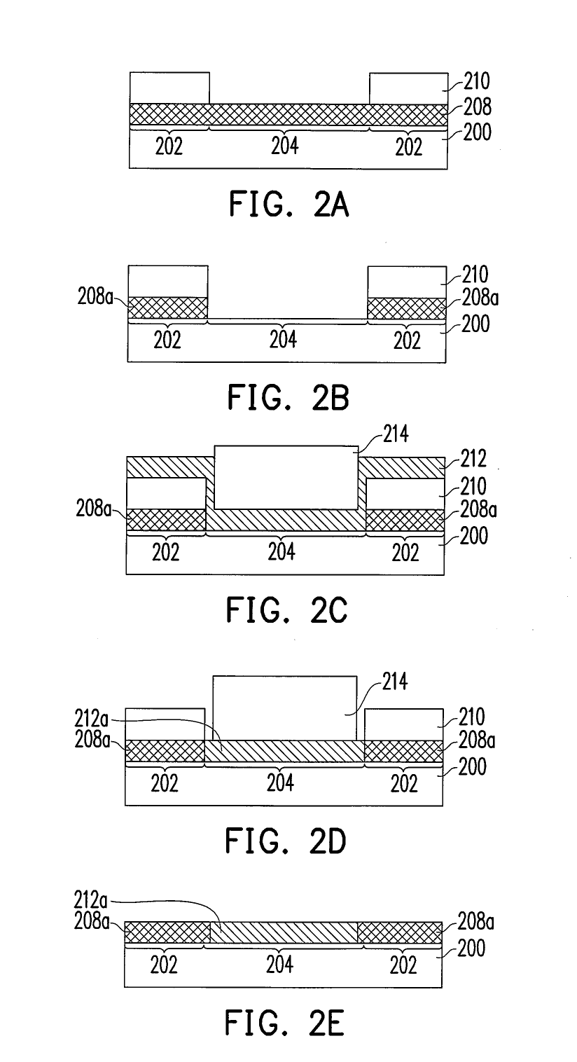

FIGS. 2A-2E are sectional views of the processes of a method of fabricating a dichroic color filter according to an first embodiment of the present invention.

Referring to FIG. 2A, the color filter of this embodiment is fabricated on a substrate 200. For example, the substrate 200 is, for example, a silicon substrate, which includes a first region 202 and a second region 204, and a conventional semiconductor element (not shown) has been formed on the substrate 200. Firstly, a first dichroic layer 208 is formed on the substrate 200, and a mask layer 210 is formed over the first region 202 of the substrate 200. The first dichroic layer 208 is, for example, one selected from among a red film, a green film, or a blue film. The mask layer 210 is, for example, a patterned photoresist layer.

Then, referring to FIG. 2B, the mask layer 210 is used as a mask to perform an etching process, so as to remove the first dichroic layer 208 not covered by the mask layer 210, and leave the first dichroic layer 208a on the first region 202.

Afterwards, referring to FIG. 2C, a second dichroic layer 212 is formed on the substrate 200, so as to cover the first mask layer 210 and the surface of the second region 204 of the substrate 200. The color of the second dichroic layer 212 is different from that of the first dichroic layer 208a, and for example, is one selected from among a red film, a green film, or a blue film. Thereafter, a mask layer 214 is formed on the second dichroic layer 212 of the second region 204, so as to expose the second dichroic layer 212 on the first region 202. The mask layer 214 is, for example, an organic material layer or a buffer layer. The organic material layer is, for example, a patterned photoresist layer. The buffer layer is, for example, polymer material such as photoresist.

Next, referring to FIG. 2D, an etch back process is performed to remove the second dichroic layer 212 on the first region 202 and between the mask layer 210 and the mask layer 214, and leave the second dichroic layer 212a on the second region 204. The etching process can be controlled through, for example, a time control method.

Next, referring to FIG. 2E, the mask layer 210 and the mask layer 214 are removed. When the materials of the mask layer 210 and the mask layer 214 are organic materials, a wet or a dry removing process, e.g., a plasma ashing process can be used to remove both of the mask layers at the same time.

In this embodiment, the etch back process is adopted, and the mask layers are used together, such that in the etching process, the second dichroic layer 212 between the mask layer 210 and the mask layer 214 is completely removed, and only the second dichroic layer 212a on the second region 204 is left due to the protection of the mask layers 210 and 214 and the control of the etching process. Thus, the finished color filter does not have the problem of edge protrusions.

### The Second Embodiment

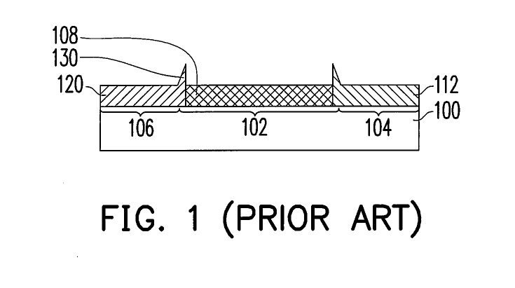

FIGS. 3A-1 to 3E-1 are sectional views of the processes of a method of fabricating a tricolor filter according to the second embodiment of the present invention.

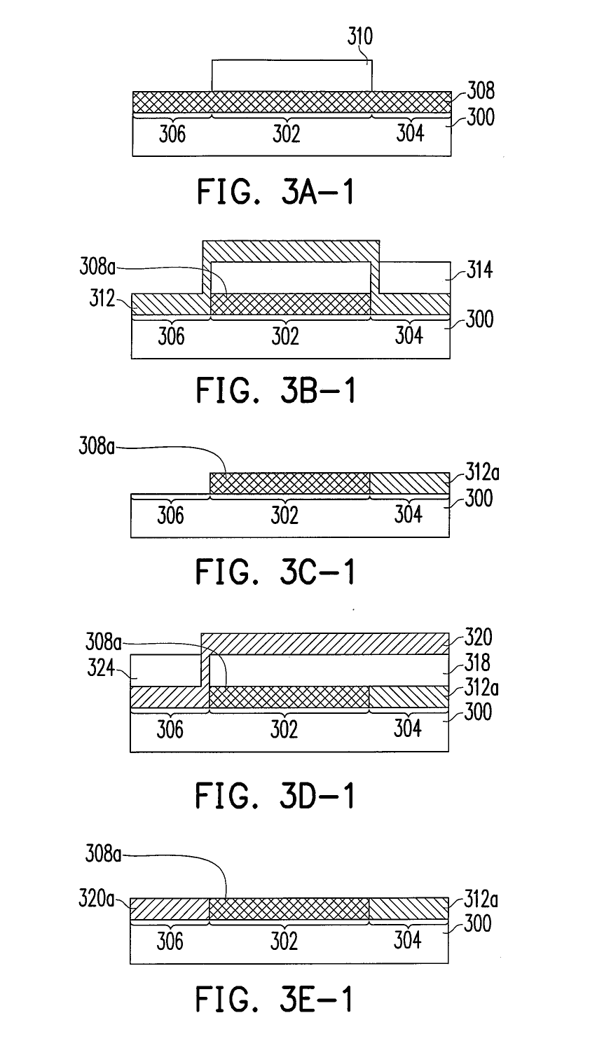

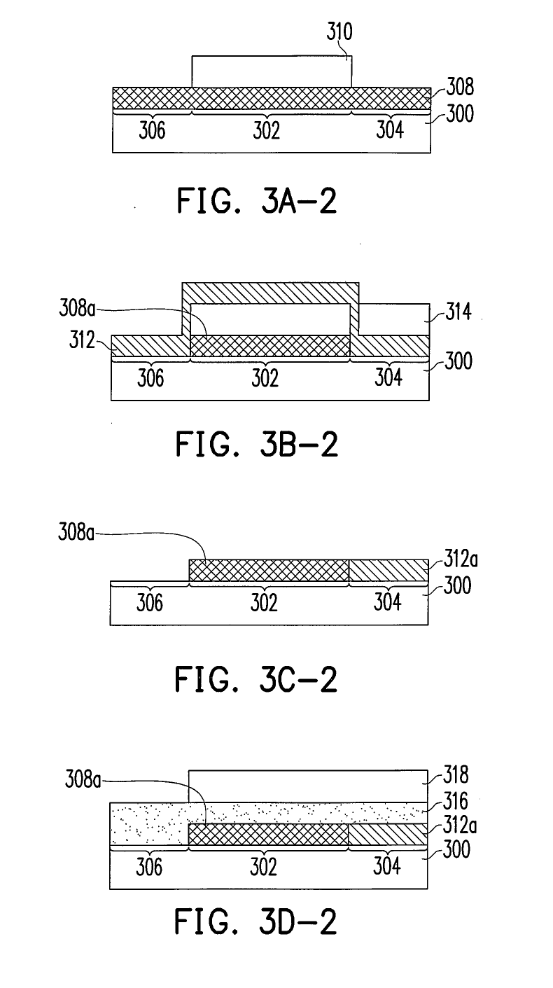

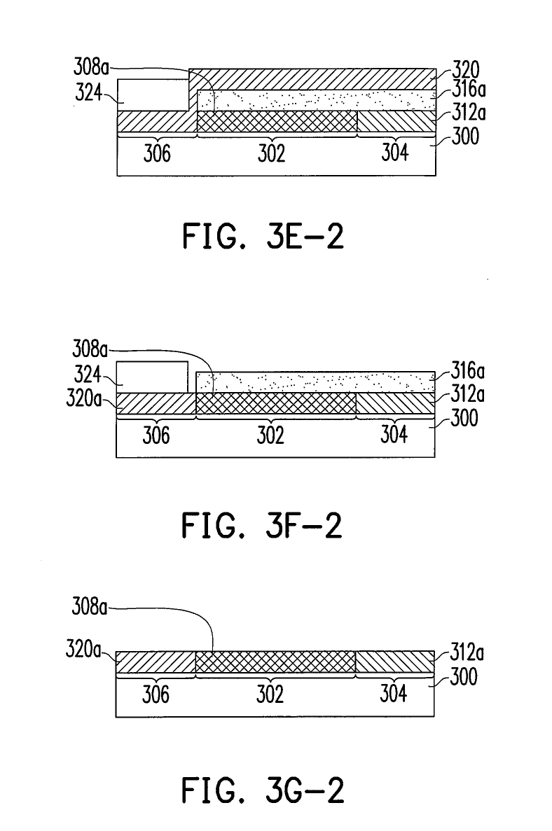

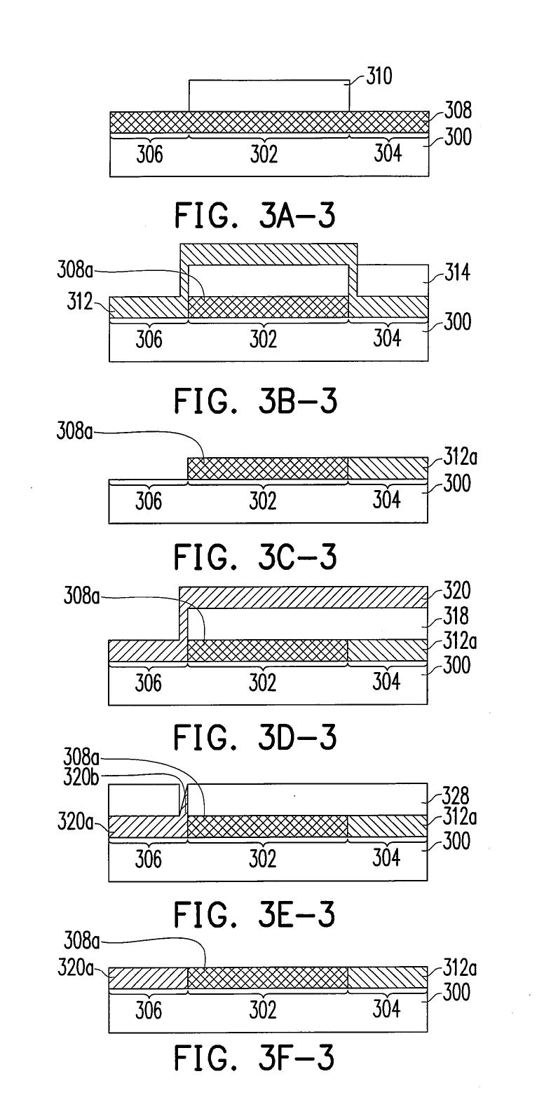

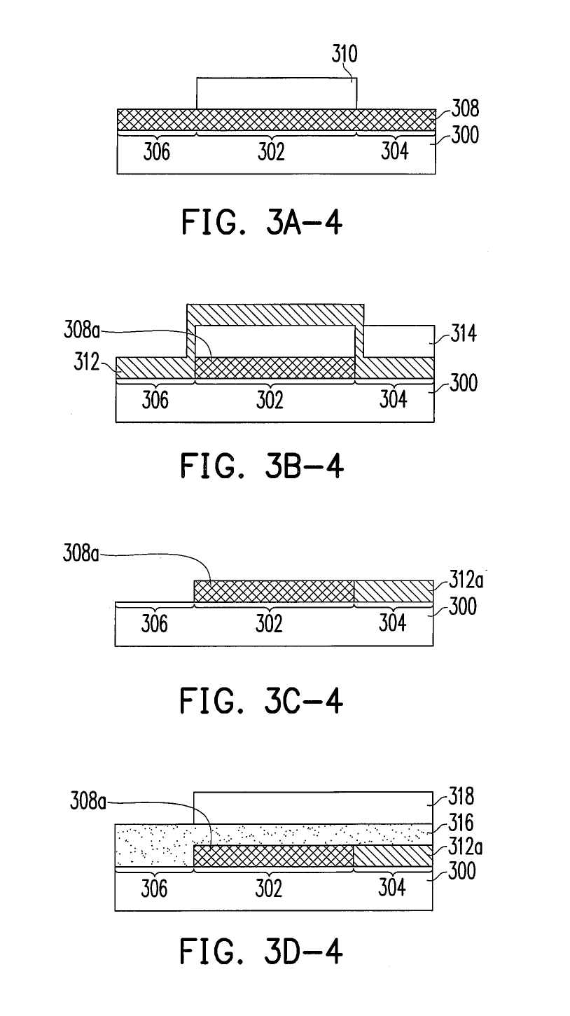

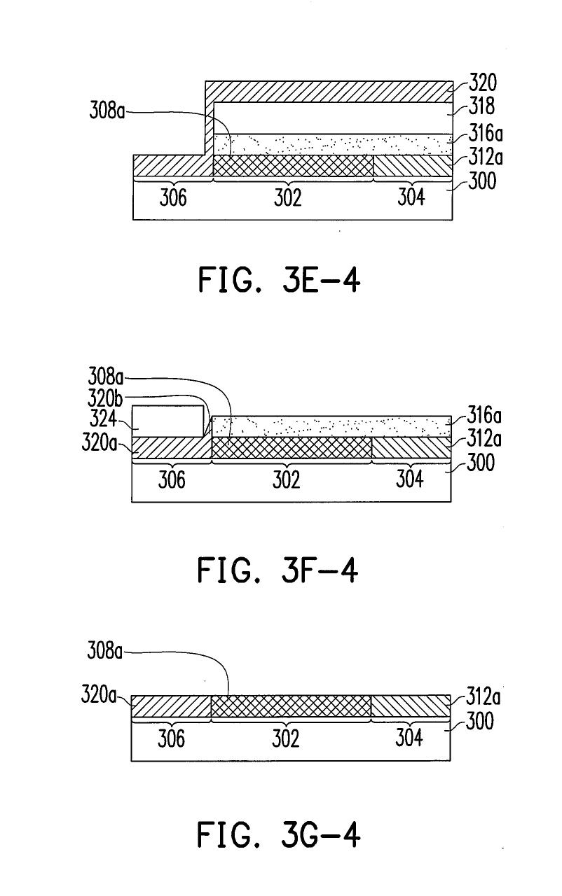

Referring to FIG. 3A-1, the color filter of this embodiment is fabricated on a substrate 300. For example, the substrate 300 is a silicon substrate including a first region 302, a second region 304, and a third region 306, and a conventional semiconductor element (not shown) has been formed on the substrate 300. Firstly, a first dichroic layer 308 is formed on the substrate 300, and a mask layer 310 is formed on the first region 302 of the substrate 300. The first dichroic layer 308 is, for example, one selected from among a red film, a green film, or a blue film. In this embodiment, the first dichroic layer 308 is, for example, a red film for illustration. The mask layer 310 is, for example, a patterned photoresist layer.

Then, referring to FIG. 3B-1, the mask layer 310 is used as a mask to perform an etching process, so as to remove the first dichroic layer 308 not covered by the mask layer 310, and leave the first dichroic layer 308a on the first region 302.

Next, a second dichroic layer 312 is formed on the substrate 300 to cover the first mask layer 310 and the surface of the second region 304 and the third region 306 of the substrate 300. The color of the second dichroic layer 312 is different from that of the first dichroic layer 308a, and for example, is one selected from among a red film, a green film, or a blue film. In this embodiment, the second dichroic layer 312 is a green film for illustration. Thereafter, a mask layer 314 is formed on the second dichroic layer 312 of the second region 304, so as to expose the second dichroic layer 312 on the first region 302 and the third region 306. The mask layer 314 is, for example, an organic material layer or a buffer layer. The organic material layer is, for example, a patterned photoresist layer. The buffer layer is, for example, polymer material such as photoresist.

Next, referring to FIG. 3C-1, an etch back process is performed to remove the second dichroic layer 312 over the first region 302 and the third region 306 and between the mask layer 310 and the mask layer 314, and leave the second dichroic layer 312a on the second region 304. The etch back process can be controlled through, for example, a time control method. Then, the mask layer 310 and the mask layer 314 are removed to expose the first dichroic layer 308a and the second dichroic layer 312a. When the materials of the mask layer 310 and the mask layer 314 are organic materials, a wet or a dry removing process, e.g., a plasma ashing process can be used to remove both of the mask layers at the same time.

Thereafter, referring to FIG. 3D-1, another mask layer 318 is formed on the first dichroic layer 308a and the second dichroic layer 312a on the first region 302 and the second region 304. The mask layer 318 is, for example, a patterned photoresist layer. Next, a third dichroic layer 320 is formed on the substrate 300 to cover the mask layer 318 and the surface of the third region 306 of the substrate 300. The color of the third dichroic layer 320 is different from that of the first dichroic layer 308a and the second dichroic layer 312a, and for example, is one selected from among a red film, a green film, or a blue film. In this embodiment, the third dichroic layer 320 is a blue film for illustration.

Thereafter, a mask layer 324 is formed on the third dichroic layer 320 on the third region 306. The mask layer 324 is, for example, an organic material layer or a buffer layer. The organic material layer is, for example, a patterned photoresist layer. The buffer layer is, for example, polymer material such as photoresist.

Then, referring to FIG. 3E-1, the third dichroic layer 320 is etched back, so as to remove the third dichroic layer 320 on the mask layer 318 and between the mask layers 318 and 324, and leave the third dichroic layer 320a on the third region 306. The etch back process can be controlled through, for example, a time control method.

Next, the mask layers 318 and 324 are removed to expose the first dichroic layer 308a, the second dichroic layer 312a, and the third dichroic layer 320a on the first region 302, the second region 304, and the third region 306. When the materials of the mask layers 318 and 324 are organic materials, a wet or a dry removing process, e.g., a plasma ashing process can be used to remove both of the mask layers at the same time.

In this embodiment, a double etch back process is adopted, and a plurality of mask layers is used together, so as to form the second dichroic layer and the third dichroic layer. During the process of etching, the dichroic layers between the mask layers are completely removed, and only the second dichroic layer and the third dichroic layer on the second region and the third region are left due to the protection of the mask layers and the control of the etching process. Thus, the finished color filter does not have the problem of edge protrusions.

### The Third Embodiment

FIGS. 3A-2 to 3G-2 are sectional views of the processes of a method of fabricating a tricolor filter according to the third embodiment of the present invention.

Referring to FIG. 3A-2, the color filter of this embodiment is fabricated on a substrate 300. For example, the substrate 300 is a silicon substrate including a first region 302, a second region 304, and a third region 306, and a conventional semiconductor element (not shown) has been formed on the substrate 300. Firstly, a first dichroic layer 308 is formed on the substrate 300, and a mask layer 310 is formed on the first region 302 of the substrate 300. The first dichroic layer 308, for example, is one selected from among a red film, a green film, or a blue film. In this embodiment, the first dichroic layer 308 is, for example, a red film for illustration. The mask layer 310 is, for example, a patterned photoresist layer.

Then, referring to FIG. 3B-2, the mask layer 310 is used as a mask to perform an etching process, so as to remove the first dichroic layer 308 not covered by the mask layer 310, and leave the first dichroic layer 308a on the first region 302.

Next, a second dichroic layer 312 is formed on the substrate 300 to cover the first mask layer 310 and the surface of the second region 304 and the third region 306 of the substrate 300. The color of the second dichroic layer 312 is different from that of the first dichroic layer 308a, and for example, is one selected from among a red film, a green film, or a blue film. In this embodiment, the second dichroic layer 312 is, for example, a green film for illustration. Thereafter, a mask layer 314 is formed on the second dichroic layer 312 of the second region 304, so as to expose the second dichroic layer 312 on the first region 302 and the third region 306. The mask layer 314 is, for example, an organic material layer or a buffer layer. The organic material layer is, for example, a patterned photoresist layer. The buffer layer is, for example, polymer material such as photoresist.

Next, referring to FIG. 3C-2, an etch back process is performed to remove the second dichroic layer 312 on the first region 302 and the third region 306 and between the mask layer 310 and the mask layer 314, and leave the second dichroic layer 312a on the second region 304. The etch back process can be controlled through, for example, a time control method. Then, the mask layer 310 and the mask layer 314 are removed to expose the first dichroic layer 308a and the second dichroic layer 312a. When the materials of the mask layer 310 and the mask layer 314 are organic materials, a wet or a dry removing process, e.g., a plasma ashing process can be used to remove both of the mask layers at the same time.

Then, referring to FIG. 3D-2, an inter layer 316 is formed on the substrate 300, and a mask layer 318 is formed on the inter layer 316 of the first region 302 and the second region 304. The material of the inter layer 316 is, for example, an insulating material, such as silicon oxide or spin on glass (SOG). The mask layer 318 is, for example, a patterned photoresist layer.

Then, referring to FIG. 3E-2, an etching process is performed to remove the inter layer 316 not covered by the mask layer 318, and leave the inter layer 316a on the first dichroic layer 308a and the second dichroic layer 312a. The etching process can be a dry or a wet etching process.

Next, the mask layer 318 is removed, and a third dichroic layer 320 is formed on the substrate 300 to cover the inter layer 316a and the surface of the third region 306 of the substrate 300. The color of the third dichroic layer 320 is different from that of the first dichroic layer 308a and the second dichroic layer 312a, and for example, is one selected from among a red film, a green film, or a blue film. In this embodiment, the third dichroic layer 320 is, for example, a blue film for illustration.

Thereafter, a mask layer 324 is formed on the third dichroic layer 320 on the third region 306. The mask layer 324 is, for example, an organic material layer or a buffer layer. The organic material layer is, for example, a patterned photoresist layer. The buffer layer is, for example, polymer material such as photoresist.

Then, referring to FIG. 3F-2, the third dichroic layer 320 is etched back, so as to remove the third dichroic layer 320 on the mask layer 318 and between the mask layer 324 and the inter layer 316a, and leave the third dichroic layer 320a on the third region 306. The etch back process can be controlled through, for example, a time control method.

Next, referring to FIG. 3G-2, the mask layer 324 and the inter layer 316a are removed to expose the first dichroic layer 308a, the second dichroic layer 312a, and the third dichroic layer 320a on the first region 302, the second region 304, and the third region 306. When the materials of the mask layers 318 and 324 are organic materials, a wet or a dry removing process, e.g., a plasma ashing process can be used to remove both of the mask layers at the same time. When the inter layer 316a is spin on glass, the wet etching process, for example, with hydrofluoric acid as an etching solution can be adopted to remove the inter layer.

In this embodiment, a double etch back process is adopted, and a plurality of mask layers and an inter layer are used together, so as to form the second dichroic layer and the third dichroic layer. During the process of etching, the dichroic layers between the inter layer and the mask layers are completely removed, and only the second dichroic layer and the third dichroic layer on the second region and the third region are left due to the protection of the mask layers and the inter layer and the control of the etching process. Thus, the finished color filter does not have the problem of edge protrusions.

### The Fourth Embodiment

FIGS. 3A-3 to 3F-3 are sectional views of the processes of a method of fabricating a tricolor filter according to the fourth embodiment of the present invention.

Referring to FIG. 3A-3, the color filter of this embodiment is fabricated on a substrate 300. For example, the substrate 300 is a silicon substrate including a first region 302, a second region 304, and a third region 306, and a conventional semiconductor element (not shown) has been formed on the substrate 300. Firstly, a first dichroic layer 308 is formed on the substrate 300, and a mask layer 310 is formed on the first region 302 of the substrate 300. The first dichroic layer 308, for example, is one selected from among a red film, a green film, or a blue film. In this embodiment, the first dichroic layer 308 is, for example, a red film for illustration. The mask layer 310 is, for example, a patterned photoresist layer.

Then, referring to FIG. 3B-3, the mask layer 310 is used as a mask to perform an etching process, so as to remove the first dichroic layer 308 not covered by the mask layer 310, and leave the first dichroic layer 308a on the first region 302.

Next, a second dichroic layer 312 is formed on the substrate 300 to cover the first mask layer 310 and the surface of the second region 304 and the third region 306 of the substrate 300. The color of the second dichroic layer 312 is different from that of the first dichroic layer 308a, and for example, is one selected from among a red film, a green film, or a blue film. In this embodiment, the second dichroic layer 312 is, for example, a green film for illustration. Thereafter, a mask layer 314 is formed on the second dichroic layer 312 of the second region 304, so as to expose the second dichroic layer 312 on the first region 302 and the third region 306. The mask layer 314 is, for example, an organic material layer or a buffer layer. The organic material layer is, for example, a patterned photoresist layer. The buffer layer is, for example, polymer material such as photoresist.

Next, referring to FIG. 3C-3, an etch back process is performed to remove the second dichroic layer 312 on the first region 302 and the third region 306 and between the mask layer 310 and the mask layer 314, and leave the second dichroic layer 312a on the second region 304. The etch back process can be controlled through, for example, a time control method. Then, the mask layer 310 and the mask layer 314 are removed to expose the first dichroic layer 308a and the second dichroic layer 312a. When the materials of the mask layer 310 and the mask layer 314 are organic materials, a wet or a dry removing process, e.g., a plasma ashing process can be used to remove both of the mask layers at the same time.

Thereafter, referring to FIG. 3D-3, another mask layer 318 is formed on the first dichroic layer 308a and the second dichroic layer 312a on the first region 302 and the second region 304. The mask layer 318 is, for example, a patterned photoresist layer. Next, a third dichroic layer 320 is formed on the substrate 300 to cover the mask layer 318 and the surface of the third region 306 of the substrate 300. The color of the third dichroic layer 320 is different from that of the first dichroic layer 308a and the second dichroic layer 312a, and for example, is one selected from among a red film, a green film, or a blue film. In this embodiment, the third dichroic layer 320 a blue film layer is, for example, a blue film for illustration.

Then, referring to FIG. 3E-3, a lift-off process is performed to remove the mask layer 318 and the third dichroic layer 320 thereon, and leave the third dichroic layer 320a on the third region 306 and an edge protrusion 320b. The lift-off process can be implemented with a wet removing process.

Then, a mask layer 328 is formed on the first, the second, and the third dichroic layers 308a, 312a, and 320a to expose the edge protrusion 320b. The mask layer 328 is, for example, an organic material layer or a buffer layer. The organic material layer is, for example, a patterned photoresist layer. The buffer layer is, for example, polymer material such as photoresist.

Next, referring to FIG. 3F-3, the edge protrusion 320b is etched away using the mask layer 328 as a mask. Then, the mask layer 328 is removed to expose the first dichroic layer 308a, the second dichroic layer 312a, and the third dichroic layer 320a on the first region 302, the second region 304, and the third region 306. The mask layer 328 can be removed through a wet or a dry removing process.

In this embodiment, a single etch back process and a single lift-off process are used, and a plurality of mask layers is used together, so as to form the second dichroic layer and the third dichroic layer. During the process of etching the second dichroic layer, the second dichroic layer between the mask layers is completely removed, and only the second dichroic layer on the second region is left due to the protection of the mask layers and the control of the etching process. The edge protrusion left on the third dichroic layer in the lift-off process is removed with the mask layers through the etching process. Thus, the finished color filter does not have the problem of edge protrusions.

### The Fifth Embodiment

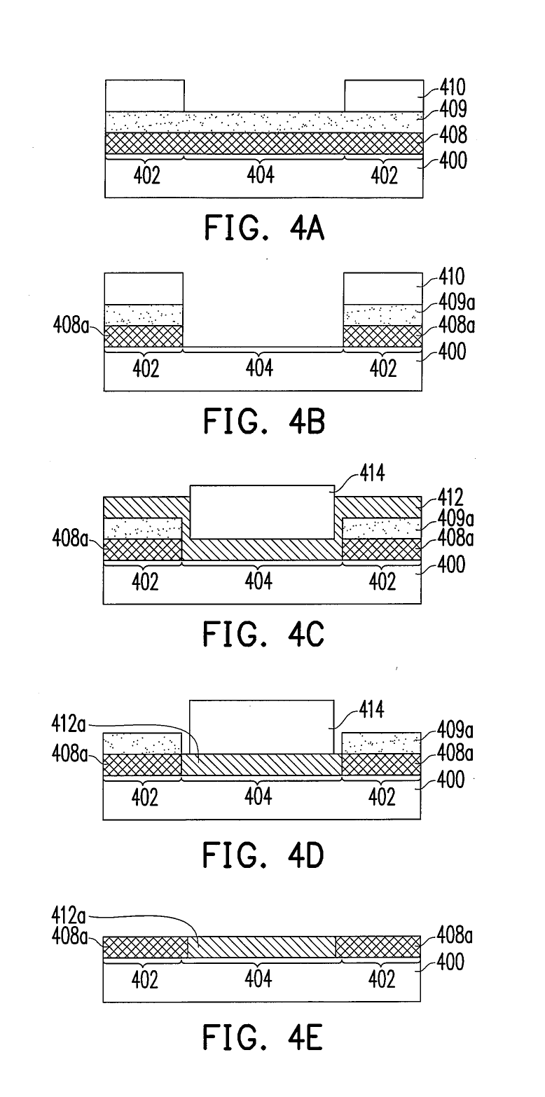

FIGS. 3A-4 to 3G-4 are sectional views of the processes of a method of fabricating a tricolor filter according to the fifth embodiment of the present invention.

Referring to FIG. 3A-4, the color filter of this embodiment is fabricated on a substrate 300. For example, the substrate 300 is a silicon substrate including a first region 302, a second region 304, and a third region 306, and a conventional semiconductor element (not shown) has been formed on the substrate 300. Firstly, a first dichroic layer 308 is formed on the substrate 300, and a mask layer 310 is formed on the first region 302 of the substrate 300. The first dichroic layer 308 is, for example, one selected from among a red film, a green film, or a blue film. In this embodiment, the first dichroic layer 308 is, for example, a red film for illustration. The mask layer 310 is, for example, a patterned photoresist layer.

Then, referring to FIG. 3B-4, the mask layer 310 is used as a mask to perform an etching process, so as to remove the first dichroic layer 308 not covered by the mask layer 310, and leave the first dichroic layer 308a on the first region 302.

Next, a second dichroic layer 312 is formed on the substrate 300 to cover the first mask layer 310 and the surface of the second region 304 and the third region 306 of the substrate 300. The color of the second dichroic layer 312 is different from that of the first dichroic layer 308a, and for example, is one selected from among a red film, a green film, or a blue film. In this embodiment, the second dichroic layer 312 is, for example, a green film for illustration. Thereafter, a mask layer 314 is formed on the second dichroic layer 312 of the second region 304, so as to expose the second dichroic layer 312 on the first region 302 and the third region 306. The mask layer 314 is, for example, an organic material layer or a buffer layer. The organic material layer is, for example, a patterned photoresist layer. The buffer layer is, for example, polymer material such as photoresist.

Next, referring to FIG. 3C-4, an etch back process is performed to remove the second dichroic layer 312 on the first region 302 and the third region 306 and between the mask layer 310 and the mask layer 314, and leave the second dichroic layer 312a on the second region 304. The etch back process can be controlled through, for example, a time control method. Then, the mask layer 310 and the mask layer 314 are removed to expose the first dichroic layer 308a and the second dichroic layer 312a. When the materials of the mask layer 310 and the mask layer 314 are organic materials, a wet or a dry removing process, e.g., a plasma ashing process can be used to remove both of the mask layers at the same time.

Then, referring to FIG. 3D-4, an inter layer 316 is formed on the substrate 300, and a mask layer 318 is formed on the inter layer 316 of the first region 302 and the second region 304. The material of the inter layer 316 is, for example, an insulating material, such as silicon oxide or spin on glass (SOG). The mask layer 318 is, for example, a patterned photoresist layer.

Then, referring to FIG. 3E-4, an etching process is performed to remove the inter layer 316 not covered by the mask layer 318, and leave the inter layer 316a on the first dichroic layer 308a and the second dichroic layer 312a. The etching process can be a dry or a wet etching process.

Next, a third dichroic layer 320 is formed on the substrate 300 to cover the mask layer 318 and the surface of the third region 306 of the substrate 300. The color of the third dichroic layer 320 is different from that of the first dichroic layer 308a and the second dichroic layer 312a, and for example, is one selected from among a red film, a green film, or a blue film. In this embodiment, the third dichroic layer 320 is, for example, a blue film for illustration.

Then, referring to FIG. 3F-3, a lift-off process is performed to remove the mask layer 318 and the third dichroic layer 320 thereon, and leave the third dichroic layer 320a on the third region 306 and an edge protrusion 320b. The lift-off process can be implemented with a wet removing process.

Afterwards, a mask layer 324 is formed on the third dichroic layer 320 on the third region 306, so as to expose the edge protrusion 320b. The mask layer 324 is, for example, an organic material layer or a buffer layer. The organic material layer is, for example, a patterned photoresist layer. The buffer layer is, for example, polymer material such as photoresist.

Next, referring to FIG. 3G-4, the edge protrusion 320b is etched away using the mask layer 324 and the inter layer 316a as a mask to etch away. Then, the mask layer 324 and the inter layer 316a are removed to expose the first dichroic layer 308a, the second dichroic layer 312a, and the third dichroic layer 320a on the first region 302, the second region 304, and the third region 306. When the material of the mask layer 324 is an organic material, a wet or a dry removing process, e.g., a plasma ashing process can be used to remove the mask layer 324. When the inter layer 316a is spin on glass, the wet etching process, for example, with hydrofluoric acid as the etching solution can be adopted to remove the inter layer.

In this embodiment, a single etch back process and a single lift-off process are used, and a plurality of mask layers and inter layer are used together, so as to form the second dichroic layer and the third dichroic layer. During the process of etching the second dichroic layer, the second dichroic layer between the mask layers is completely removed, and only the second dichroic layer on the second region is left due to the protection of the mask layers and the control of the etching process. The edge protrusion left on the third dichroic layer in the lift-off process can be removed with the inter layer and the mask layers formed after the lift-off process as the mask through the etching process. Thus, the finished color filter does not have the problem of edge protrusions.

### The Sixth Embodiment

FIGS. 4A-4E are sectional views of the processes of a method of fabricating a dichroic color filter according to the sixth embodiment of the present invention.

Referring to FIG. 4A, the color filter of this embodiment is fabricated on a substrate 400. For example, the substrate 400 is a silicon substrate including a first region 402 and a second region 404, and a conventional semiconductor element (not shown) has been formed on the substrate 400. Firstly, a first dichroic layer 408 and an inter layer 409 are formed on the substrate 400, and a mask layer 410 is formed over the first region 402 of the substrate 400. The first dichroic layer 408 is, for example, one selected from among a red film, a green film, or a blue film. The material of the inter layer 409 is, for example, an insulating material, such as silicon oxide or spin on glass. The mask layer 410 is, for example, a patterned photoresist layer.

Then, referring to FIG. 4B, the mask layer 410 is used as a mask to perform an etching process, so as to remove the inter layer 409 and the first dichroic layer 408 not covered by the mask layer 410, and leave the inter layer 409a and the first dichroic layer 408a on the first region 402.

Next, referring to FIG. 4C, the mask layer 410 is removed, and a second dichroic layer 412 is formed on the substrate 400 to cover the inter layer 409a and the surface of the second region 404 of the substrate 400. The color of the second dichroic layer 412 is different from that of the first dichroic layer 408a, and for example, is one selected from among a red film, a green film, or a blue film. Thereafter, a mask layer 414 is formed on the second dichroic layer 412 of the second region 404, so as to expose the second dichroic layer 412 on the first region 402. The mask layer 414 is, for example, an organic material layer or a buffer layer. The organic material layer is, for example, a patterned photoresist layer. The buffer layer is, for example, polymer material such as photoresist.

Next, referring to FIG. 4D, an etch back process is performed to remove the second dichroic layer 412 on the first region 402 and between the mask layer 414 and the inter layer 409a, and leave the second dichroic layer 412a on the second region 404. The etching process can be controlled through, for example, a time control method.

Next, referring to FIG. 4E, the mask layer 414 and the inter layer 409a are removed. The mask layer 414 is removed through a wet or a dry removing process, e.g., a plasma ashing process. When the inter layer 409a is spin on glass, the wet etching process, for example, with hydrofluoric acid as the etching solution can be used to remove the inter layer.

The second dichroic layer of this embodiment is formed on the inter layer instead of the photoresist layer. Therefore, it is prevented that the photoresist layer contaminates a deposition chamber during the process of depositing the second dichroic layer. In this embodiment, the etch back process is adopted, and the mask layers and the inter layer are used together, such that in the etching process, the second dichroic layer between the mask layer and the inter layer is completely removed, and only the second dichroic layer on the second region is left due to the protection of the mask layers and the inter layers and the control of the etching process. Thus, the finished color filter does not have the problem of edge protrusions.

### The Seventh Embodiment

FIGS. 5A-1 to 5G-1 are sectional views of the processes of a method of fabricating a tricolor filter according to the seventh embodiment of the present invention.

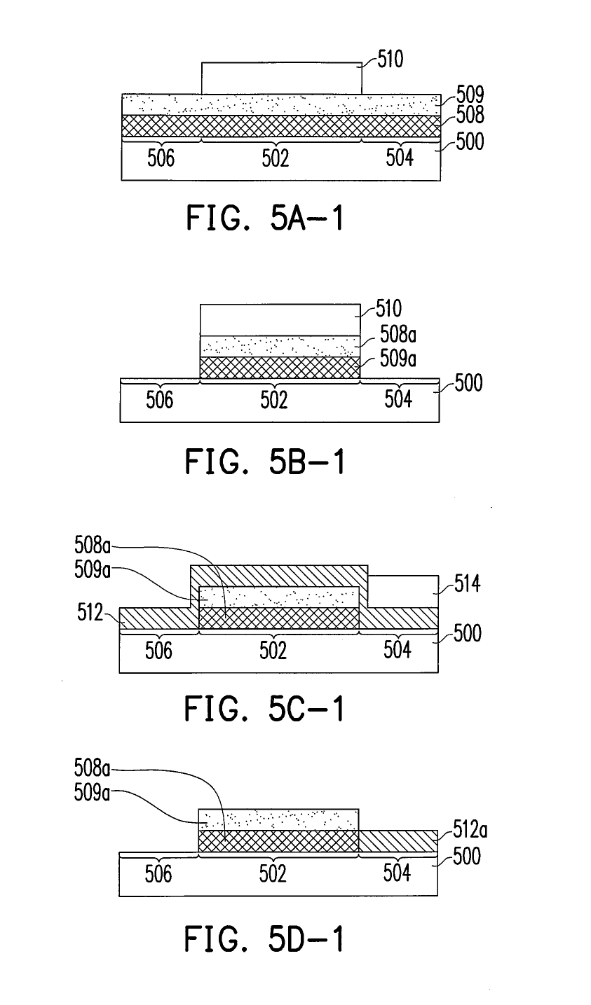

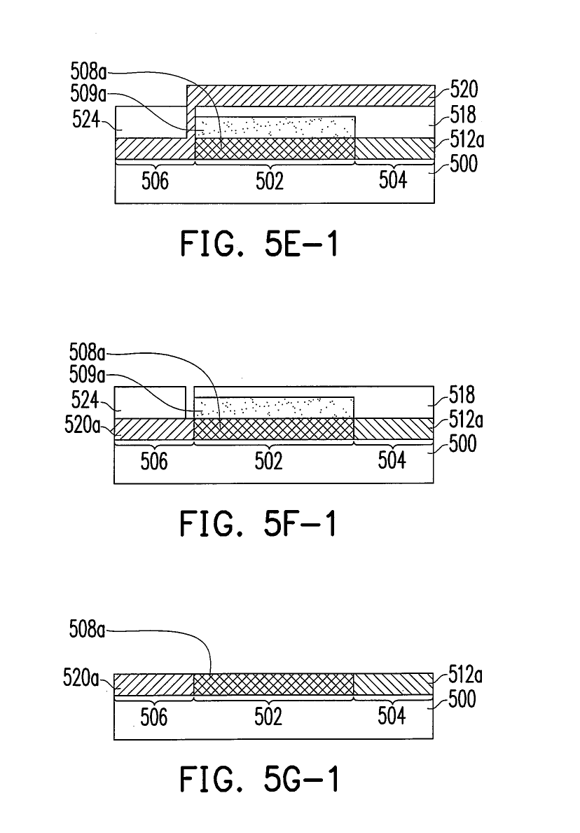

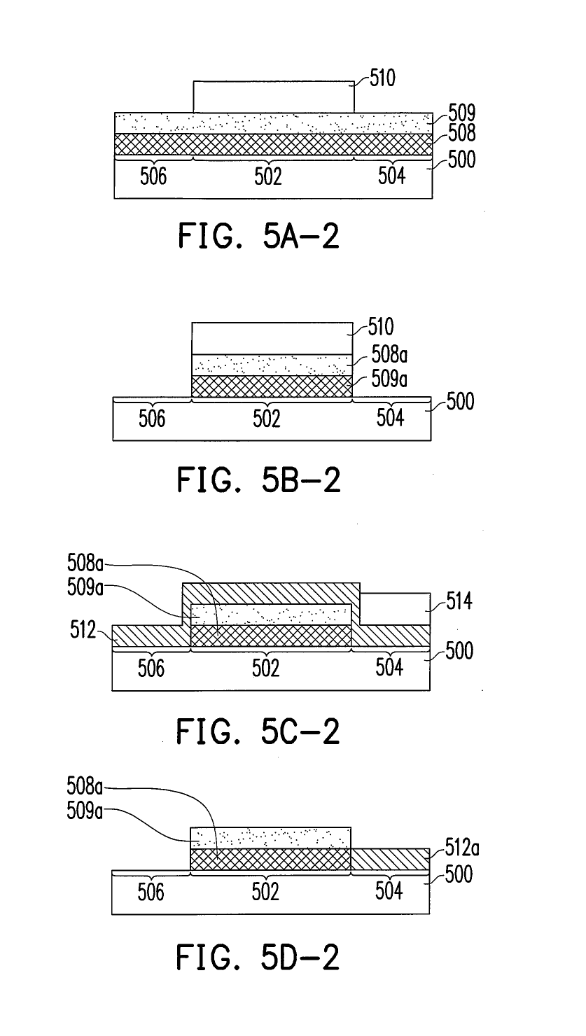

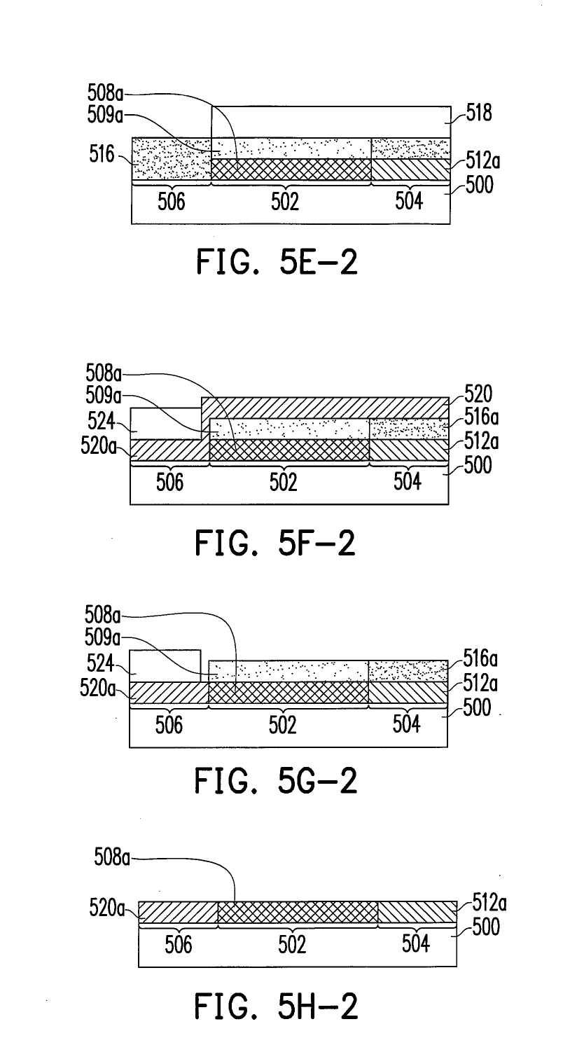

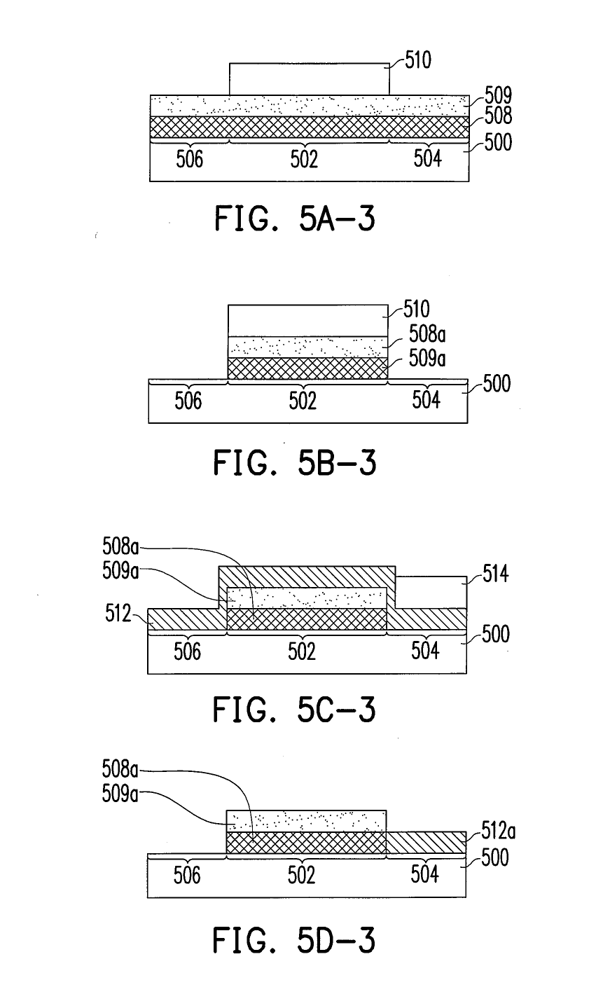

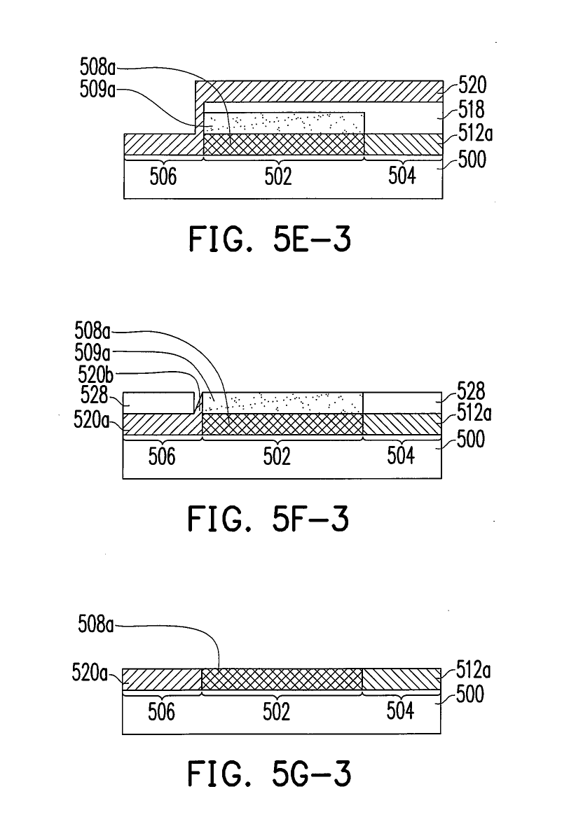

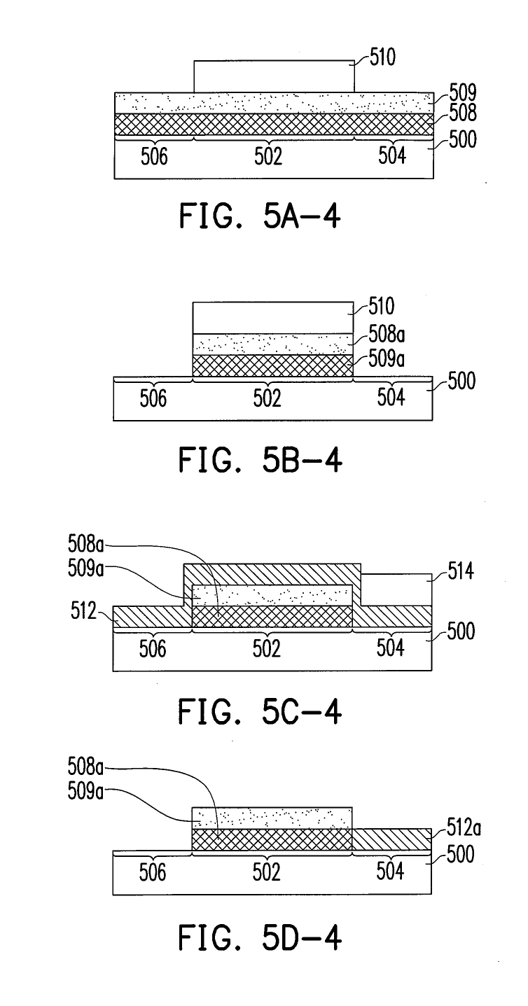

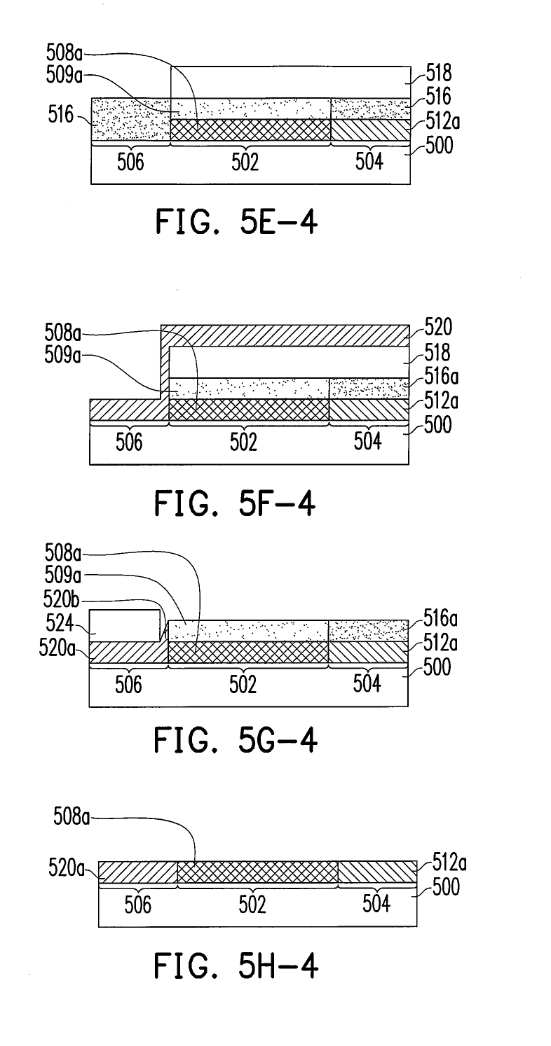

Referring to FIG. 5A-1, the color filter of this embodiment is fabricated on a substrate 500. For example, the substrate 500 is a silicon substrate including a first region 502, a second region 504, and a third region 506, and a conventional semiconductor element (not shown) has been formed on the substrate 500. Firstly, a first dichroic layer 508 and an inter layer 509 are formed on the substrate 500, and a mask layer 510 is formed over the first region 502 of the substrate 500. The first dichroic layer 508 is, for example, one selected from among a red film, a green film, or a blue film. In this embodiment, the first dichroic layer 508 is, for example, a red film for illustration. The material of the inter layer 509 is, for example, an insulating material, such as silicon oxide or spin on glass. The mask layer 510 is, for example, a patterned photoresist layer.

Then, referring to FIG. 5B-1, the mask layer 510 is used as a mask to perform an etching process, so as to remove the inter layer 509 and the first dichroic layer 508 not covered by the mask layer 510, and leave the inter layer 509a and the first dichroic layer 508a on the first region 502.

Next, referring to FIG. 5C-1, the mask layer 510 is removed, and a second dichroic layer 512 is formed on the substrate 500 to cover the inter layer 509a and the surface of the second region 504 and the third region 506 of the substrate 500. The color of the second dichroic layer 512 is different from that of the first dichroic layer 508a, and for example, is one selected from among a red film, a green film, or a blue film. In this embodiment, the second dichroic layer 512 is, for example, a green film for illustration. Thereafter, a mask layer 514 is formed on the second dichroic layer 512 of the second region 504, so as to expose the second dichroic layer 512 on the first region 502 and the third region 506. The mask layer 514 is, for example, an organic material layer or a buffer layer. The organic material layer is, for example, a patterned photoresist layer. The buffer layer is, for example, polymer material such as photoresist.

Next, referring to FIG. 5D-1, an etch back process is performed to remove the second dichroic layer 512 on the first region 502 and between the mask layer 514 and the inter layer 509a, so as to expose the inter layer 509a, and leave the second dichroic layer 512a on the second region 504. The etching process can be controlled through, for example, a time control method. Then, the mask layer 514 is removed through a wet or a dry removing process, e.g., a plasma ashing process.

Thereafter, referring to FIG. 5E-1, another mask layer 518 is formed on the first region 502 and the second region 504. The mask layer 518 is, for example, a patterned photoresist layer. Next, a third dichroic layer 520 is formed on the substrate 500 to cover the mask layer 518 and the surface of the third region 506 of the substrate 500. The color of the third dichroic layer 520 is different from that of the first dichroic layer 508a and the second dichroic layer 512a, and for example, is one selected from among a red film, a green film, or a blue film. In this embodiment, the third dichroic layer 520 is, for example, a blue film for illustration.

Thereafter, a mask layer 524 is formed on the third dichroic layer 520 on the third region 506. The mask layer 524 is, for example, an organic material layer or a buffer layer. The organic material layer is, for example, a patterned photoresist layer. The buffer layer is, for example, polymer material such as photoresist.

Then, referring to FIG. 5F-1, the third dichroic layer 520 is etched back, so as to remove the third dichroic layer 520 on the mask layer 518 and between the mask layer 524 and the inter layer 509a, and leave the third dichroic layer 520a on the third region 506. The etch back process can be controlled through, for example, a time control method.

Next, referring to FIG. 5G-1, the mask layers 518 and 524 and the inter layer 509a are removed to expose the first dichroic layer 508a, the second dichroic layer 512a, and the third dichroic layer 520a on the first region 502, the second region 504, and the third region 506. When the materials of the mask layers 518 and 524 are organic materials, a wet or a dry removing process, e.g., a plasma ashing process can be used to remove both of the mask layers at the same time. When the inter layer 509a is spin on glass, the wet etching process, for example, with hydrofluoric acid as the etching solution can be used to remove the inter layer.

The second dichroic layer of this embodiment is formed on the inter layer instead of the photoresist layer. Therefore, it is prevented that the photoresist layer contaminates the deposition chamber during the process of depositing the second dichroic layer. In this embodiment, a double etch back process is adopted, and the inter layer and the mask layers are used together, so as to form the second dichroic layer and the third dichroic layer. During the processes of etching, the second and the third dichroic layers between the mask layers and the inter layer are completely removed, and only the second dichroic layer and the third dichroic layer on the second region and the third region are left due to the protection of the mask layers and the inter layer and the control of the etching process. Thus, the finished color filter does not have the problem of edge protrusions.

### The Eighth Embodiment

FIGS. 5A-2 to 5H-2 are sectional views of the processes of a method of fabricating a tricolor filter according to the eighth embodiment of the present invention.

Referring to FIG. 5A-2, the color filter of this embodiment is fabricated on a substrate 500. For example, the substrate 500 is a silicon substrate including a first region 502, a second region 504, and a third region 506, and a conventional semiconductor element (not shown) has been formed on the substrate 500. Firstly, a first dichroic layer 508 and an inter layer 509 are formed on the substrate 500, and a mask layer 510 is formed over the first region 502 of the substrate 500. The first dichroic layer 508 is, for example, one selected from among a red film, a green film, or a blue film. In this embodiment, the first dichroic layer 508 is, for example, a red film for illustration. The material of the inter layer 509 is, for example, an insulating material, such as silicon oxide or spin on glass. The mask layer 510 is, for example, a patterned photoresist layer.

Then, referring to FIG. 5B-2, the mask layer 510 is used as a mask to perform an etching process, so as to remove the inter layer 509 and the first dichroic layer 508 not covered by the mask layer 510, and leave the inter layer 509a and the first dichroic layer 508a on the first region 502.

Next, referring to FIG. 5C-2, the mask layer 510 is removed, and a second dichroic layer 512 is formed on the substrate 500 to cover the inter layer 509a and the surface of the second region 504 and the third region 506 of the substrate 500. The color of the second dichroic layer 512 is different from that of the first dichroic layer 508a, and for example, is one selected from among a red film, a green film, or a blue film. In this embodiment, the second dichroic layer 512 is, for example, a green film for illustration. Thereafter, a mask layer 514 is formed on the second dichroic layer 512 of the second region 504, so as to expose the second dichroic layer 512 on the first region 502 and the third region 506. The mask layer 514 is, for example, an organic material layer or a buffer layer. The organic material layer is, for example, a patterned photoresist layer. The buffer layer is, for example, polymer material such as photoresist.

Next, referring to FIG. 5D-2, an etch back process is performed to remove the second dichroic layer 512 on the first region 502 and between the mask layer 514 and the inter layer 509a, so as to expose the inter layer 509a, and leave the second dichroic layer 512a on the second region 504. The etching process can be controlled through, for example, a time control method. Then, the mask layer 514 is removed through a wet or a dry removing process, e.g., a plasma ashing process.

Then, referring to FIG. 5E-2, an inter layer 516 is formed on the substrate 500, and a mask layer 518 is formed on the inter layers 509a and 516 of the first region 502 and the second region 504. The material of the inter layer 516 is, for example, an insulating material, such as silicon oxide or spin on glass (SOG). The mask layer 518 is, for example, a patterned photoresist layer.

Then, referring to FIG. 5F-2, an etching process is performed to remove the inter layer 516 not covered by the mask layer 518, and leave the inter layers 509a and 516a on the first dichroic layer 508a and the second dichroic layer 512a. The etching process can be a dry or a wet etching process.

Next, the mask layer 518 is removed, and a third dichroic layer 520 is formed on the substrate 500 to cover the inter layers 509a and 516a and the surface of the third region 506 of the substrate 500. The color of the third dichroic layer 520 is different from that of the first dichroic layer 508a and the second dichroic layer 512a, and for example, is one selected from among a red film, a green film, or a blue film. In this embodiment, the third dichroic layer 520 is, for example, a blue film for illustration.

Thereafter, a mask layer 524 is formed on the third dichroic layer 520 on the third region 506. The mask layer 524 is, for example, an organic material layer or a buffer layer. The organic material layer is, for example, a patterned photoresist layer. The buffer layer is, for example, polymer material such as photoresist.

Then, referring to FIG. 5G-2, the third dichroic layer 520 is etched back, so as to remove the third dichroic layer 520 on the mask layer 518 and between the mask layer 524 and the inter layer 516a, and leave the third dichroic layer 520a on the third region 506. The etch back process can be controlled through, for example, a time control method.

Next, referring to FIG. 5H-2, the mask layer 524 and the inter layers 509a and 516a are removed to expose the first dichroic layer 508a, the second dichroic layer 512a, and the third dichroic layer 520a on the first region 502, the second region 504, and the third region 506. When the material of the mask layer 524 is an organic material, a wet or a dry removing process, e.g., a plasma ashing process can be used to remove the mask layer. When the inter layers 509a and 516a are spin on glass, the wet etching process, for example, with hydrofluoric acid as the etching solution can be used to remove the inter layers.

The second dichroic layer and the third dichroic layer of this embodiment are formed on the inter layer instead of the photoresist layer. Therefore, it is prevented that the photoresist layer contaminates the deposition chamber during the process of depositing the second dichroic layer. In this embodiment, a double etch back process is used, and a plurality of mask layers and two inter layers are used together, so as to form the second dichroic layer and the third dichroic layer. During the process of etching, the dichroic layers between the inter layers and the mask layers are completely removed, and only the second dichroic layer and the third dichroic layer on the second region and the third region are left due to the protection of the mask layers and the inter layer and the control of the etching process. Thus, the finished color filter does not have the problem of edge protrusions.

### The Ninth Embodiment

FIGS. 5A-3 to 5G-3 are sectional views of the processes of a method of fabricating a tricolor filter according to the ninth embodiment of the present invention.

Referring to FIG. 5A-3, the color filter of this embodiment is fabricated on a substrate 500. For example, the substrate 500 is a silicon substrate including a first region 502, a second region 504, and a third region 506, and a conventional semiconductor element (not shown) has been formed on the substrate 500. Firstly, a first dichroic layer 508 and an inter layer 509 are formed on the substrate 500, and a mask layer 510 is formed over the first region 502 of the substrate 500. The first dichroic layer 508 is, for example, one selected from among a red film, a green film, or a blue film. In this embodiment, the first dichroic layer 508 is, for example, a red film for illustration. The material of the inter layer 509 is, for example, an insulating material, such as silicon oxide or spin on glass. The mask layer 510 is, for example, a patterned photoresist layer.

Then, referring to FIG. 5B-3, the mask layer 510 is used as a mask to perform an etching process, so as to remove the inter layer 509 and the first dichroic layer 508 not covered by the mask layer 510, and leave the inter layer 509a and the first dichroic layer 508a on the first region 502.

Next, referring to FIG. 5C-3, the mask layer 510 is removed, and a second dichroic layer 512 is formed on the substrate 500 to cover the inter layer 509a and the surface of the second region 504 and the third region 506 of the substrate 500. The color of the second dichroic layer 512 is different from that of the first dichroic layer 508a, and for example, is one selected from among a red film, a green film, or a blue film. In this embodiment, the second dichroic layer 512 is, for example, a green film for illustration. Thereafter, a mask layer 514 is formed on the second dichroic layer 512 of the second region 504, so as to expose the second dichroic layer 512 on the first region 502 and the third region 506. The mask layer 514 is, for example, an organic material layer or a buffer layer. The organic material layer is, for example, a patterned photoresist layer. The buffer layer is, for example, polymer material such as photoresist.

Next, referring to FIG. 5D-3, an etch back process is performed to remove the second dichroic layer 512 on the first region 502 and between the mask layer 514 and the inter layer 509a, so as to expose the inter layer 509a, and leave the second dichroic layer 512a on the second region 504. The etching process can be controlled through, for example, a time control method. Then, the mask layer 514 is removed through a wet or a dry removing process, e.g., a plasma ashing process.

Thereafter, referring to FIG. 5E-3, another mask layer 518 is formed on the first dichroic layer 508a and the second dichroic layer 512a on the first region 502 and the second region 504. The mask layer 518 is, for example, a patterned photoresist layer. Next, a third dichroic layer 520 is formed on the substrate 500 to cover the mask layer 518 and the surface of the third region 506 of the substrate 500. The color of the third dichroic layer 520 is different from that of the first dichroic layer 508a and the second dichroic layer 512a, and for example, is one selected from among a red film, a green film, or a blue film. In this embodiment, the third dichroic layer 520 is, for example, a blue film for illustration.

Then, referring to FIG. 5F-3, a lift-off process is performed to remove the mask layer 518 and the third dichroic layer 520 thereon, and leave the third dichroic layer 520a on the third region 506 and an edge protrusion 520b. The lift-off process can be implemented with a wet removing process.

Then, a mask layer 528 is formed on the second, and the third dichroic layers 512a, and 520a to expose the edge protrusion 520b. The mask layer 528 is, for example, an organic material layer or a buffer layer. The organic material layer is, for example, a patterned photoresist layer. The buffer layer is, for example, polymer material such as photoresist.

Next, referring to FIG. 5G-3, to etch away the edge protrusion 520b is etched away using the mask layer 528 as a mask. Then, the mask layer 528 is removed to expose the first dichroic layer 508a, the second dichroic layer 512a, and the third dichroic layer 520a on the first region 502, the second region 504, and the third region 506. The mask layer 528 can be removed through a wet or a dry removing process.

The second dichroic layer of this embodiment is formed on the inter layer instead of the photoresist layer. Therefore, it is prevented that the photoresist layer contaminates the deposition chamber during the process of depositing the second dichroic layer. Moreover, in this embodiment, a single etch back process and a single lift-off process are used, and a plurality of mask layers and inter layers are used together, so as to form the second dichroic layer and the third dichroic layer. During the process of etching the second dichroic layer, the second dichroic layer between the mask layers is completely removed, and only the second dichroic layer on the second region is left due to the protection of the mask layers and the control of the etching process. The edge protrusion left on the third dichroic layer in the lift-off process is removed with the mask layers through the etching process. Thus, the finished color filter does not have the problem of edge protrusions.

### The Tenth Embodiment

FIGS. 5A-4 to 5H-4 are sectional views of the processes of a method of fabricating a tricolor filter according to the tenth embodiment of the present invention.

Referring to FIG. 5A-4, the color filter of this embodiment is fabricated on a substrate 500. For example, the substrate 500 is a silicon substrate including a first region 502, a second region 504, and a third region 506, and a conventional semiconductor element (not shown) has been formed on the substrate 500. Firstly, a first dichroic layer 508 and an inter layer 509 are formed on the substrate 500, and a mask layer 510 is formed over the first region 502 of the substrate 500. The first dichroic layer 508 is, for example, one selected from among a red film, a green film, or a blue film. In this embodiment, the first dichroic layer 508 is, for example, a red film for illustration. The material of the inter layer 509 is, for example, an insulating material, such as silicon oxide or spin on glass. The mask layer 510 is, for example, a patterned photoresist layer.

Then, referring to FIG. 5B-4, the mask layer 510 is used as a mask to perform an etching process, so as to remove the inter layer 509 and the first dichroic layer 508 not covered by the mask layer 510, and leave the inter layer 509a and the first dichroic layer 508a on the first region 502.

Next, referring to FIG. 5C-4, the mask layer 510 is removed, and a second dichroic layer 512 is formed on the substrate 500 to cover the inter layer 509a and the surface of the second region 504 and the third region 506 of the substrate 500. The color of the second dichroic layer 512 is different from that of the first dichroic layer 508a, and for example, is one selected from among a red film, a green film, or a blue film. In this embodiment, the second dichroic layer 512 is, for example, a green film for illustration. Thereafter, a mask layer 514 is formed on the second dichroic layer 512 of the second region 504, so as to expose the second dichroic layer 512 on the first region 502 and the third region 506. The mask layer 514 is, for example, an organic material layer or a buffer layer. The organic material layer is, for example, a patterned photoresist layer. The buffer layer is, for example, polymer material such as photoresist.

Next, referring to FIG. 5D-4, an etch back process is performed to remove the second dichroic layer 512 on the first region 502 and between the mask layer 514 and the inter layer 509a, so as to expose the inter layer 509a, and leave the second dichroic layer 512a on the second region 504. The etching process can be controlled through, for example, a time control method. Then, the mask layer 514 is removed through a wet or a dry removing process, e.g., a plasma ashing process.

Then, referring to FIG. 5E-4, an inter layer 516 is formed on the substrate 500, and a mask layer 518 is formed on the inter layers 509a and 516 of the first region 502 and the second region 504. The material of the inter layer 516 is, for example, an insulating material, such as silicon oxide or spin on glass (SOG). The mask layer 518 is, for example, a patterned photoresist layer.

Then, referring to FIG. 5F-4, an etching process is performed to remove the inter layer 516 not covered by the mask layer 518, and leave the inter layers 509a and 516a on the first dichroic layer 508a and the second dichroic layer 512a. The etching process can be a dry etching or a wet etching process.

Then, referring to FIG. 5G-4, a lift-off process is performed to remove the mask layer 518 and the third dichroic layer 520 thereon, and leave the third dichroic layer 520a on the third region 506 and an edge protrusion 520b. The lift-off process can be implemented with a wet removing process.

Afterwards, a mask layer 524 is formed on the third dichroic layer 520 on the third region 506, so as to expose the edge protrusion 520b. The mask layer 524 is, for example, an organic material layer or a buffer layer. The organic material layer is, for example, a patterned photoresist layer. The buffer layer is, for example, polymer material such as photoresist.

Next, referring to FIG. 5H-4, the edge protrusion 520b is etched away using the mask layer 524 and the inter layers 509a and 516a as a mask. Then, the mask layer 524 and the inter layer 516a are removed to expose the first dichroic layer 508a, the second dichroic layer 512a, and the third dichroic layer 520a on the first region 502, the second region 504, and the third region 506. When the material of the mask layer 524 is an organic material, a wet or a dry removing process, e.g., a plasma ashing process can be used to remove the mask layer. When the inter layers 509a and 516a are spin on glass, the wet etching process, for example, with hydrofluoric acid as the etching solution can be used to remove the inter layers.

The second dichroic layer of this embodiment is formed on the inter layer instead of the photoresist layer. Therefore, it is prevented that the photoresist layer contaminates the deposition chamber during the process of depositing the second dichroic layer. Moreover, in this embodiment, a single etch back process and a single lift-off process are used, and a plurality of mask layers and inter layers are used, so as to form the second dichroic layer and the third dichroic layer. During the process of etching the second dichroic layer, the second dichroic layer between the mask layers is completely removed, and only the second dichroic layer on the second region is left due to the protection of the mask layers and the control of the etching process. The edge protrusion left on the third dichroic layer in the lift-off process is removed with the mask layers and the inter layers through the etching process. Thus, the finished color filter does not have the problem of edge protrusions.

### The Eleventh Embodiment

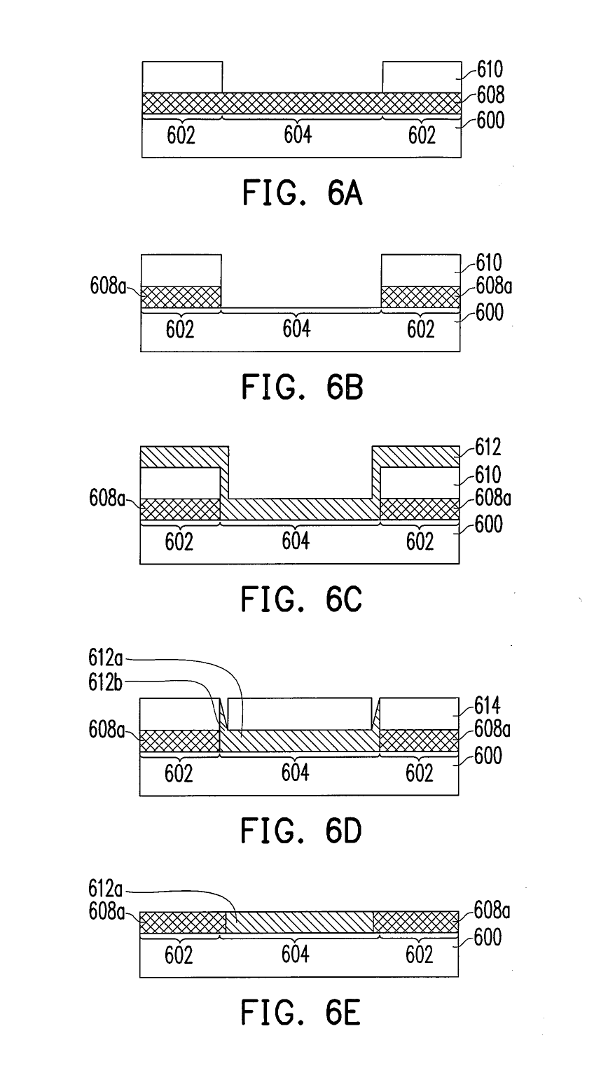

FIGS. 6A-6E are sectional views of the processes of a method of fabricating a dichroic color filter according to the eleventh embodiment of the present invention.

Referring to FIG. 6A, the color filter of this embodiment is fabricated on a substrate 600. For example, the substrate 600 is a silicon substrate including a first region 602 and a second region 604, and a conventional semiconductor element (not shown) has been formed on the substrate 600. Firstly, a first dichroic layer 608 is formed on the substrate 600, and a mask layer 610 is formed over the first region 602 of the substrate 600. The first dichroic layer 608 is, for example, one selected from among a red film, a green film, or a blue film. The mask layer 610 is, for example, a patterned photoresist layer.

Then, referring to FIG. 6B, the mask layer 610 is used as a mask to perform an etching process, so as to remove the first dichroic layer 608 not covered by the mask layer 610, and leave the first dichroic layer 608a on the first region 602.

Afterwards, referring to FIG. 6C, a second dichroic layer 612 is formed on the substrate 600, so as to cover the mask layer 610a and the surface of the second region 604 of the substrate 600. The color of the second dichroic layer 612 is different from that of the first dichroic layer 608a, and for example, is one selected from among a red film, a green film, or a blue film.

Then, referring to FIG. 6D, a lift-off process is performed to remove the second dichroic layer 612 on the mask layer 610, and leave the second dichroic layer 612a and an edge protrusion 612b on the second region 604. The lift-off process can be implemented with a wet removing process.

Next, a mask layer 614 is formed on the first dichroic layer 608a and the second dichroic layer 612a on the first region 602 and the second region 604, so as to expose the edge protrusion 612b. The mask layer 614 is, for example, an organic material layer or a buffer layer. The organic material layer is, for example, a patterned photoresist layer. The buffer layer is, for example, polymer material such as photoresist.

Next, referring to FIG. 6E, the edge protrusion 612b is etched away using the mask layer 614 as a mask. Then, the mask layer 614 is removed to expose the first dichroic layer 608a and the second dichroic layer 612a on the first region 602 and the second region 604. The mask layer 614 can be removed through a wet or a dry removing process.

In this embodiment, a single lift-off process is used first, and then the mask layers and the etching process are used to form the second dichroic layer. The edge protrusion left after the lift-off process for forming the second dichroic layer in the second region can be completely removed with the mask layers through the etching process. Therefore, the finished color filter does not have the problem of edge protrusions.

### The Twelfth Embodiment

FIGS. 7A-1 to 7E-1 are sectional views of the processes of a method of fabricating a tricolor filter according to the twelfth embodiment of the present invention.

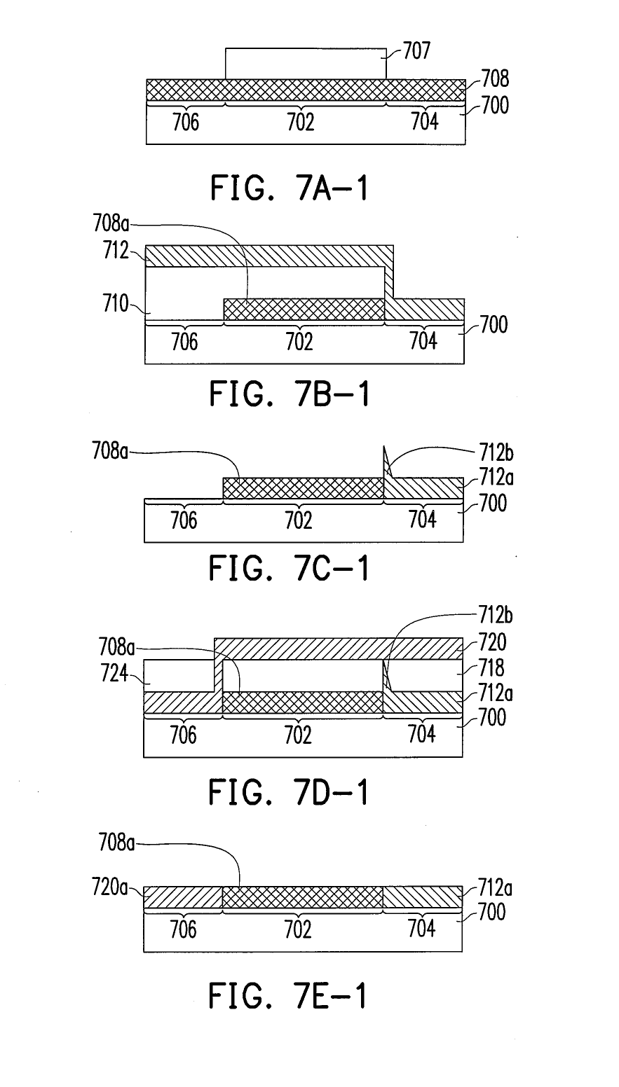

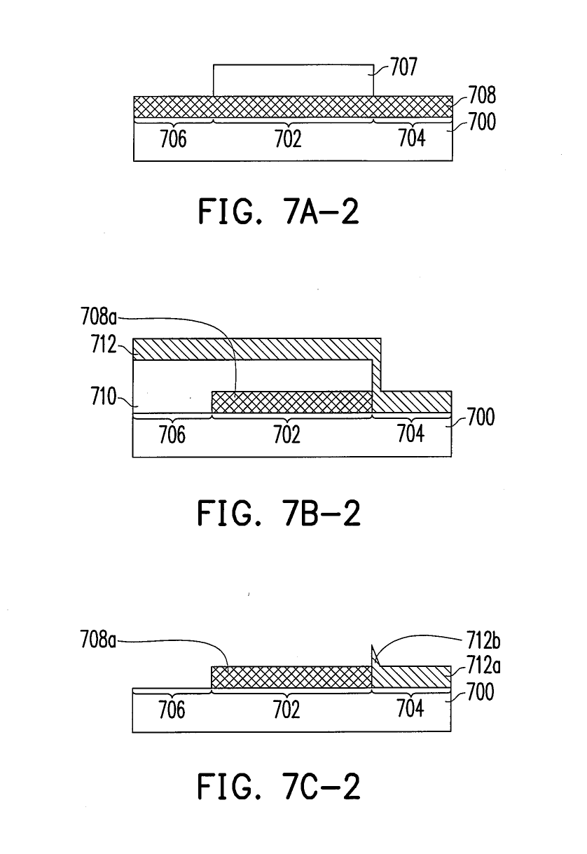

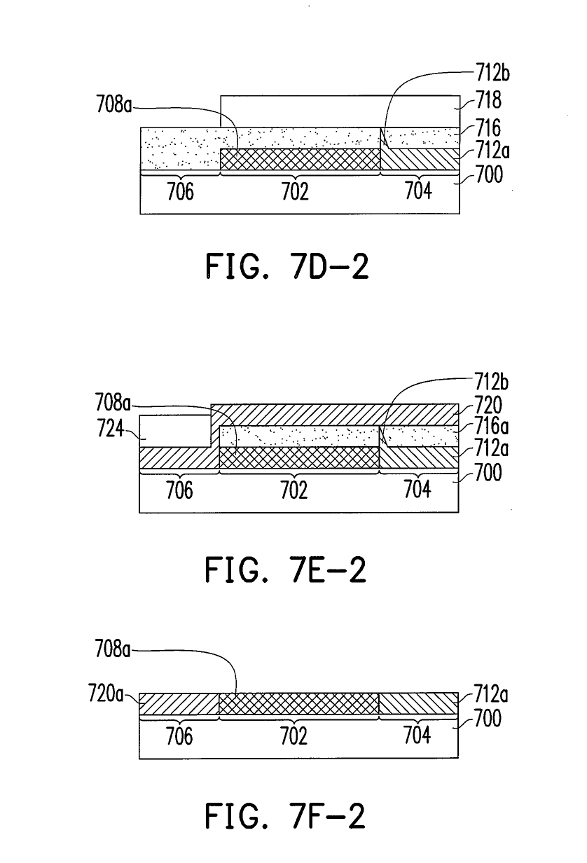

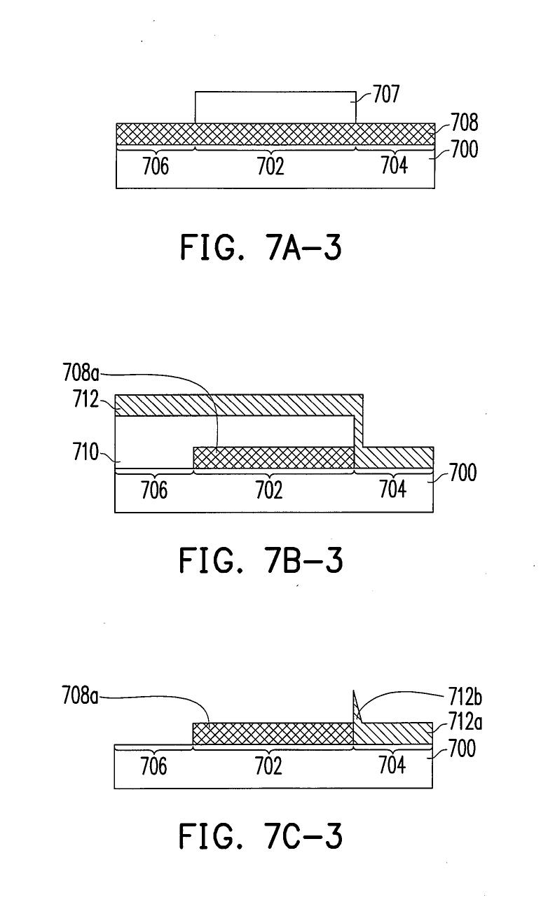

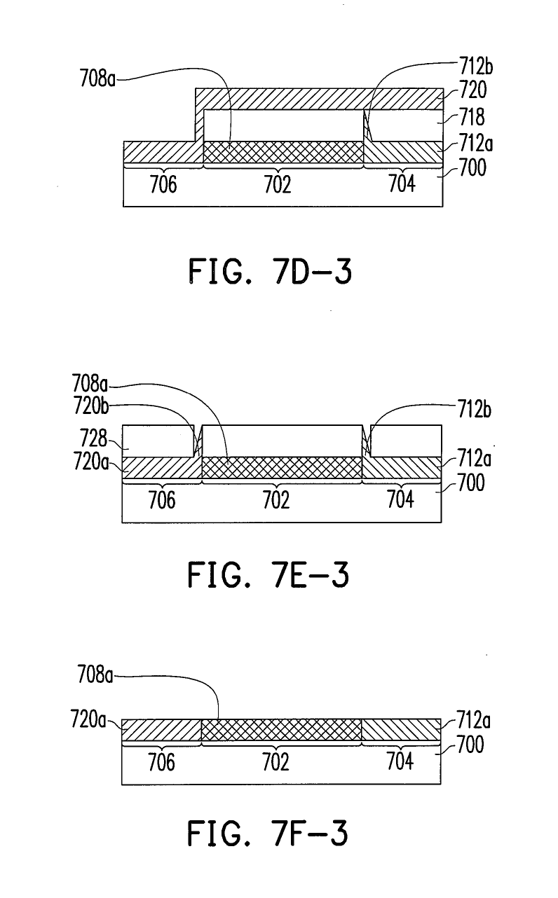

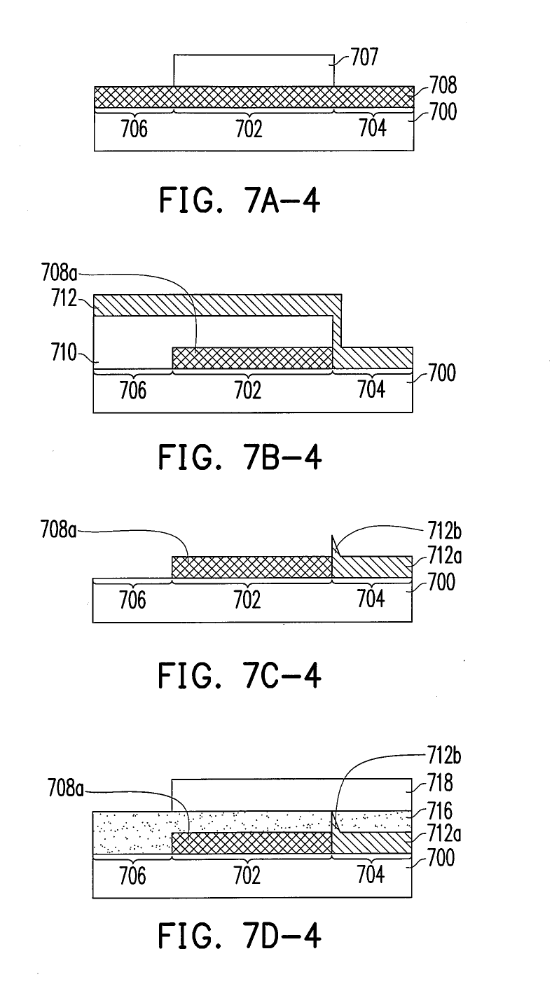

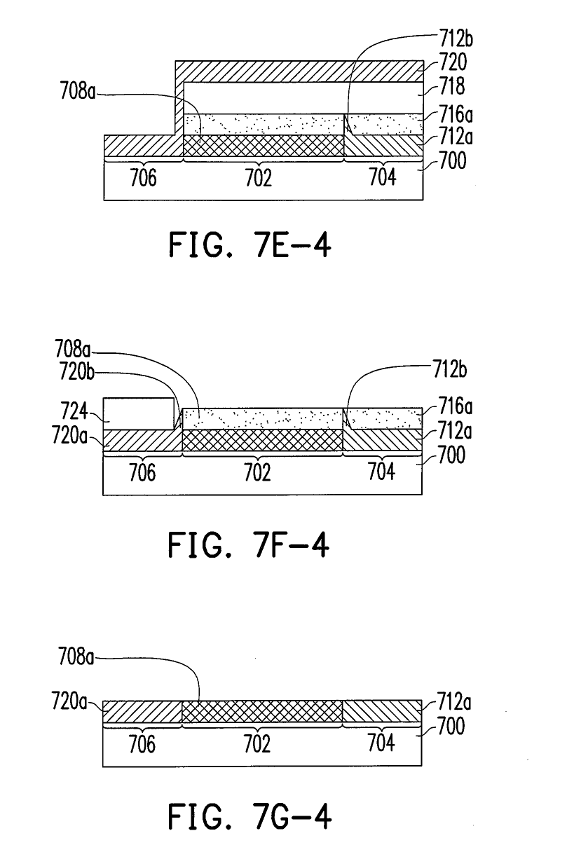

Referring to FIG. 7A-1, the color filter of this embodiment is fabricated on a substrate 700. For example, the substrate 700 is a silicon substrate including a first region 702, a second region 704, and a third region 706, and a conventional semiconductor element (not shown) has been formed on the substrate 700. Firstly, a first dichroic layer 708 is formed on the substrate 700, and a mask layer 707 is formed over the first region 702 of the substrate 700. The first dichroic layer 708 is, for example, one selected from among a red film, a green film, or a blue film. In this embodiment, the first dichroic layer 708 is, for example, a red film for illustration. The mask layer 707 is, for example, a patterned photoresist layer.

Then, referring to FIG. 7B-1, the mask layer 707 is used as a mask to perform an etching process, so as to remove the first dichroic layer 708 not covered by the mask layer 710, and leave the first dichroic layer 708a on the first region 702. Then, the mask layer 707 is removed through a wet or a dry removing process.

Then, a mask layer 710 is formed on the first dichroic layer 708a on the first region 702 and the surface of the third region 708a of the substrate 700. The mask layer 710 is, for example, a patterned photoresist layer. Next, a second dichroic layer 712 is formed on the substrate 700 to cover the mask layer 710 and the surface of the second region 704 of the substrate 700. The color of the second dichroic layer 712 is different from that of the first dichroic layer 708a, and for example, is one selected from among a red film, a green film, or a blue film. In this embodiment, the second dichroic layer 712 is, for example, a green film for illustration.

Then, referring to FIG. 7C-1, a lift-off process is performed to remove the second dichroic layer 712 on the mask layer 710, and leave the second dichroic layer 712a and an edge protrusion 712b on the second region 704. The lift-off process can be implemented with a wet removing process.

Thereafter, referring to FIG. 7D-1, another mask layer 718 is formed on the first dichroic layer 708a and the second dichroic layer 712a on the first region 702 and the second region 704. In this embodiment, the mask layer 718 exposes the edge protrusion 712b. The mask layer 718 is, for example, an organic material layer or a buffer layer. The organic material layer is, for example, a patterned photoresist layer. The buffer layer is, for example, polymer material such as photoresist.

Next, a third dichroic layer 720 is formed on the substrate 700 to cover the mask layer 718 and the surface of the third region 706 of the substrate 700. The color of the third dichroic layer 720 is different from that of the first dichroic layer 708a and the second dichroic layer 712a, and for example, is one selected from among a red film, a green film, or a blue film. In this embodiment, the third dichroic layer 720 is, for example, a blue film for illustration.

Thereafter, a mask layer 724 is formed on the third dichroic layer 720 on the third region 706. The mask layer 724 is, for example, an organic material layer or a buffer layer. The organic material layer is, for example, a patterned photoresist layer. The buffer layer is, for example, polymer material such as photoresist.

Then, referring to FIG. 7E-1, the third dichroic layer 720 is etched back, so as to remove the third dichroic layer 720 on the mask layer 718 and between the mask layers 724 and etch away the edge protrusion 712b at the same time, and leave the third dichroic layer 720a on the third region 706 and the second dichroic layer 712a on the second region 704. The etch back process can be controlled through, for example, a time control method.

Next, the mask layers 718 and 724 are removed to expose the first dichroic layer 708a, the second dichroic layer 712a, and the third dichroic layer 720a on the first region 702, the second region 704, and the third region 706. When the materials of the mask layers 718 and 724 are organic materials, a wet or a dry removing process, e.g., a plasma ashing process can be used to remove both of the mask layers at the same time.

In this embodiment, a lift-off process is used first, then an etch back process is employed, and the mask layers are used together, so as to form the second dichroic layer and the third dichroic layer. During the process of etch back, due to the protection of the mask layers and the control of the etching process, the third dichroic layer between the mask layers is completely removed, the edge protrusion left in the lift-off process is removed, and only the second dichroic layer and the third dichroic layer on the second region and the third region are left. Thus, the finished color filter does not have the problem of edge protrusions.

### The Thirteenth Embodiment

FIGS. 7A-2 to 7F-2 are sectional views of the processes of a method of fabricating a tricolor filter according to the thirteenth embodiment of the present invention.

Referring to FIG. 7A-2, the color filter of this embodiment is fabricated on a substrate 700. For example, the substrate 700 is a silicon substrate including a first region 702, a second region 704, and a third region 706, and a conventional semiconductor element (not shown) has been formed on the substrate 700. Firstly, a first dichroic layer 708 is formed on the substrate 700, and a mask layer 707 is formed over the first region 702 of the substrate 700. The first dichroic layer 708 is, for example, one selected from among a red film, a green film, or a blue film. In this embodiment, the first dichroic layer 708 is, for example, a red film for illustration. The mask layer 707 is, for example, a patterned photoresist layer.

Then, referring to FIG. 7B-2, the mask layer 707 is used as a mask to perform an etching process, so as to remove the first dichroic layer 708 not covered by the mask layer 710, and leave the first dichroic layer 708a on the first region 702. Then, the mask layer 707 is removed through a wet or a dry removing process.

Then, a mask layer 710 is formed on the first dichroic layer 708a on the first region 702 and the surface of the third region 708a of the substrate 700. The mask layer 710 is, for example, a patterned photoresist layer. Next, a second dichroic layer 712 is formed on the substrate 700 to cover the mask layer 710 and the surface of the second region 704 of the substrate 700. The color of the second dichroic layer 712 is different from that of the first dichroic layer 708a, and for example, is one selected from among a red film, a green film, or a blue film. In this embodiment, the second dichroic layer 712 is, for example, a green film for illustration.

Then, referring to FIG. 7C-2, a lift-off process is performed to remove the second dichroic layer 712 on the mask layer 710, and leave the second dichroic layer 712a and an edge protrusion 712b on the second region 704. The lift-off process can be implemented with a wet removing process.

Then, referring to FIG. 7D-2, an inter layer 716 is formed on the substrate 700. The material of the inter layer 716 is, for example, an insulating material, such as silicon oxide or spin on glass (SOG). In this embodiment, the inter layer 716 exposes the edge protrusion 712b. Then, a mask layer 718 is formed on the first region 702 and the second region 704. The mask layer 718 is, for example, an organic material layer or a buffer layer. The organic material layer is, for example, a patterned photoresist layer. The buffer layer is, for example, polymer material such as photoresist.

Then, referring to FIG. 7E-2, an etching process is performed to remove the inter layer 716 not covered by the mask layer 718, and leave the inter layer 716a on the first dichroic layer 708a and the second dichroic layer 712a. The etching process can be a dry or a wet etching process.

Next, the mask layer 718 is removed, and a third dichroic layer 720 is formed on the substrate 700 to cover the inter layer 716a and the surface of the third region 706 of the substrate 700. The color of the third dichroic layer 720 is different from that of the first dichroic layer 708a and the second dichroic layer 712a, and for example, is one selected from among a red film, a green film, or a blue film. In this embodiment, the third dichroic layer 720 is, for example, a blue film for illustration.

Thereafter, a mask layer 724 is formed on the third dichroic layer 720 on the third region 706. The mask layer 724 is, for example, an organic material layer or a buffer layer. The organic material layer is, for example, a patterned photoresist layer. The buffer layer is, for example, polymer material such as photoresist.

Then, referring to FIG. 7F-2, the third dichroic layer 720 is etched back, so as to remove the third dichroic layer 720 on the mask layer 718 and between the mask layer 724 and the inter layer 716a, remove the edge protrusion 712b at the same time, and leave the third dichroic layer 720a on the third region 706. The etch back process can be controlled through, for example, a time control method.

Next, the mask layer 724 and the inter layer 716a are removed to expose the first dichroic layer 708a, the second dichroic layer 712a, and the third dichroic layer 720a on the first region 702, the second region 704, and the third region 706. When the material of the mask layer 724 is an organic material, a wet or a dry removing process, e.g., a plasma ashing process can be used to remove the mask layer. When the inter layer 716a is spin on glass, the wet etching process, for example, with hydrofluoric acid as the etching solution can be used to remove the inter layer.

The third dichroic layer of this embodiment is formed on the inter layer instead of the photoresist layer. Therefore, it is prevented that the photoresist layer contaminates the deposition chamber during the process of depositing the second dichroic layer. In this embodiment, an etch back process is used first, then a lift-off process is used, and the mask layers and the inter layer are used together, so as to form the second dichroic layer and the third dichroic layer. During the process of etching, due to the protection of the mask layers and the control of the etching process, the third dichroic layer between the mask layers is completely removed, the edge protrusion left in the lift-off process is removed, and only the second dichroic layer and the third dichroic layer on the second region and the third region are left. Thus, the finished color filter does not have the problem of edge protrusions.

### The Fourteenth Embodiment

FIGS. 7A-3 to 7F-3 are sectional views of the processes of a method of fabricating a tricolor filter according to the fourteenth embodiment of the present invention.

Referring to FIG. 7A-3, the color filter of this embodiment is fabricated on a substrate 700. For example, the substrate 700 is a silicon substrate including a first region 702, a second region 704, and a third region 706, and a conventional semiconductor element (not shown) has been formed on the substrate 700. Firstly, a first dichroic layer 708 is formed on the substrate 700, and a mask layer 707 is formed over the first region 702 of the substrate 700. The first dichroic layer 708 is, for example, one selected from among a red film, a green film, or a blue film. In this embodiment, the first dichroic layer 708 is, for example, a red film for illustration. The mask layer 707 is, for example, a patterned photoresist layer.

Then, referring to FIG. 7B-3, the mask layer 707 is used as a mask to perform an etching process, so as to remove the first dichroic layer 708 not covered by the mask layer 710, and leave the first dichroic layer 708a on the first region 702. Then, the mask layer 707 is removed through a wet or a dry removing process.

Then, a mask layer 710 is formed on the first dichroic layer 708a on the first region 702 and the surface of the third region 708a of the substrate 700. The mask layer 710 is, for example, a patterned photoresist layer. Next, a second dichroic layer 712 is formed on the substrate 700 to cover the mask layer 710 and the surface of the second region 704 of the substrate 700. The color of the second dichroic layer 712 is different from that of the first dichroic layer 708a, and for example, is one selected from among a red film, a green film, or a blue film. In this embodiment, the second dichroic layer 712 is, for example, a green film for illustration.

Then, referring to FIG. 7C-3, a lift-off process is performed to remove the second dichroic layer 712 on the mask layer 710, and leave the second dichroic layer 712a and an edge protrusion 712b on the second region 704. The lift-off process can be implemented with a wet removing process.

Thereafter, referring to FIG. 7D-3, another mask layer 718 is formed on the first dichroic layer 708a and the second dichroic layer 712a on the first region 702 and the second region 704. The mask layer 718 is, for example, a patterned photoresist layer. Next, a third dichroic layer 720 is formed on the substrate 700 to cover the mask layer 718 and the surface of the third region 706 of the substrate 700. The color of the third dichroic layer 720 is different from that of the first dichroic layer 708a and the second dichroic layer 712a, and for example, is one selected from among a red film, a green film, or a blue film. In this embodiment, the third dichroic layer 720 is, for example, a blue film for illustration.

Then, referring to FIG. 7E-3, a lift-off process is performed to remove the mask layer 718 and the third dichroic layer 720 thereon, and leave the third dichroic layer 720a on the third region 706 and an edge protrusion 720b. The lift-off process can be implemented with a wet removing process.

Then, a mask layer 728 is formed on the first, the second, and the third dichroic layers 708a, 712a, and 720a to expose the edge protrusion 720b and 712b. The mask layer 728 is, for example, an organic material layer or a buffer layer. The organic material layer is, for example, a patterned photoresist layer. The buffer layer is, for example, polymer material such as photoresist.

Next, referring to FIG. 7F-3, the edge protrusion 720b is etched away using the mask layer 728 as a mask. Then, the mask layer 728 is removed to expose the first dichroic layer 708a, the second dichroic layer 712a, and the third dichroic layer 720a on the first region 702, the second region 704, and the third region 706. The mask layer 728 can be removed through a wet or a dry removing process.

In this embodiment, a double left-off process is used, and a plurality of mask layers and the etching process are used together, so as to form the second dichroic layer and the third dichroic layer. The edge protrusions on the third dichroic layer left in the lift-off process can be removed with the mask layers through the etching process. Therefore, the finished color filter does not have the problem of edge protrusions.

### The Fifteenth Embodiment

FIGS. 7A-4 to 7G-4 are sectional views of the processes of a method of fabricating a tricolor filter according to the fifteenth embodiment of the present invention.

Referring to FIG. 7A-4, the color filter of this embodiment is fabricated on a substrate 700. For example, the substrate 700 is a silicon substrate including a first region 702, a second region 704, and a third region 706, and a conventional semiconductor element (not shown) has been formed on the substrate 700. Firstly, a first dichroic layer 708 is formed on the substrate 700, and a mask layer 707 is formed over the first region 702 of the substrate 700. The first dichroic layer 708 is, for example, one selected from among a red film, a green film, or a blue film. In this embodiment, the first dichroic layer 708 is, for example, a red film for illustration. The mask layer 707 is, for example, a patterned photoresist layer.

Then, referring to FIG. 7B-4, the mask layer 707 is used as a mask to perform an etching process, so as to remove the first dichroic layer 708 not covered by the mask layer 710, and leave the first dichroic layer 708a on the first region 702. Then, the mask layer 707 is removed through a wet or a dry removing process.

Then, a mask layer 710 is formed on the first dichroic layer 708a on the first region 702 and the surface of the third region 708a of the substrate 700. The mask layer 710 is, for example, a patterned photoresist layer. Next, a second dichroic layer 712 is formed on the substrate 700 to cover the mask layer 710 and the surface of the second region 704 of the substrate 700. The color of the second dichroic layer 712 is different from that of the first dichroic layer 708a, and for example, is one selected from among a red film, a green film, or a blue film. In this embodiment, the second dichroic layer 712 is, for example, a green film for illustration.

Then, referring to FIG. 7C-4, a lift-off process is performed to remove the second dichroic layer 712 on the mask layer 710, and leave the second dichroic layer 712a and an edge protrusion 712b on the second region 704. The lift-off process can be implemented with a wet removing process.

Then, referring to FIG. 7D-4, an inter layer 716 is formed on the substrate 700, and a mask layer 718 is formed on the inter layer 716 of the first region 702 and the second region 704. The material of the inter layer 716 is, for example, an insulating material, such as silicon oxide or spin on glass (SOG). The mask layer 718 is, for example, a patterned photoresist layer.

Then, referring to FIG. 7E-4, an etching process is performed to remove the inter layer 716 not covered by the mask layer 718, and leave the inter layer 716a on the first dichroic layer 708a and the second dichroic layer 712a. The etching process can be a dry or a wet etching process.

Next, a third dichroic layer 720 is formed on the substrate 700 to cover the mask layer 718 and the surface of the third region 706 of the substrate 700. The color of the third dichroic layer 720 is different from that of the first dichroic layer 708a and the second dichroic layer 712a, and for example, is one selected from among a red film, a green film, or a blue film. In this embodiment, the third dichroic layer 720 is, for example, a blue film for illustration.

Then, referring to FIG. 7F-4, a lift-off process is performed to remove the mask layer 718 and the third dichroic layer 720 thereon, and leave the third dichroic layer 720a and an edge protrusion 720b on the third region 706. The lift-off process can be implemented with a wet removing process.

Afterwards, a mask layer 724 is formed on the third dichroic layer 720 on the third region 706, so as to expose the edge protrusions 720b, 712b and the inter layer 716a. The mask layer 724 is, for example, an organic material layer or a buffer layer. The organic material layer is, for example, a patterned photoresist layer. The buffer layer is, for example, polymer material such as photoresist.

Next, referring to FIG. 7G-4, the edge protrusions 712b and 720b are etched away using the mask layer 724 and the inter layer 716a as a mask. Then, the mask layer 724 and the inter layer 716a are removed to expose the first dichroic layer 708a, the second dichroic layer 712a, and the third dichroic layer 720a on the first region 702, the second region 704, and the third region 706. When the material of the mask layer 724 is an organic material, a wet or a dry removing process, e.g., a plasma ashing process can be used to remove the mask layer. When the inter layer 716a is spin on glass, the wet etching process, for example, with hydrofluoric acid as the etching solution can be used to remove the inter layer.

In this embodiment, a double etch back process is used, and a plurality of mask layers and the etching process are used together, so as to form the second dichroic layer and the third dichroic layer. The edge protrusions on the third dichroic layer and on the second dichroic layer left in the lift-off processes can be removed with the mask layers and the inter layer through the etching process. Therefore, the finished color filter does not have the problem of edge protrusions.

### The Sixteenth Embodiment

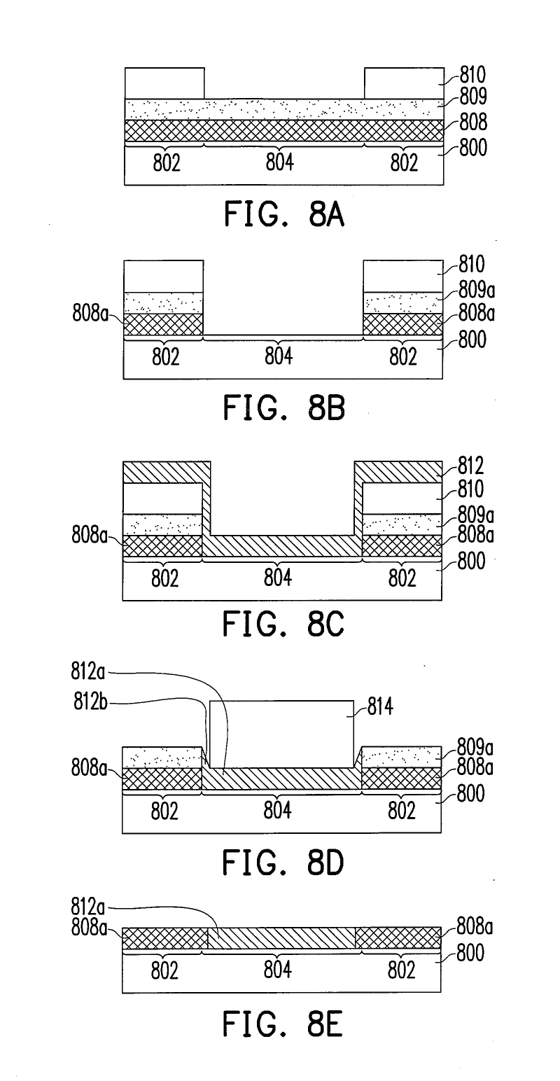

FIGS. 8A-8E are sectional views of the processes of a method of fabricating a dichroic color filter according to the sixteenth embodiment of the present invention.

Referring to FIG. 8A, the color filter of this embodiment is fabricated on a substrate 800. For example, the substrate 800 is a silicon substrate including a first region 802 and a second region 804, and a conventional semiconductor element (not shown) has been formed on the substrate 800. Firstly, a first dichroic layer 808 and an inter layer 809 are formed on the substrate 800, and a mask layer 810 is formed over the first region 802 of the substrate 800. The first dichroic layer 808 is, for example, one selected from among a red film, a green film, or a blue film. The material of the inter layer 809 is, for example, an insulating material, such as silicon oxide or spin on glass. The mask layer 810 is, for example, a patterned photoresist layer.

Then, referring to FIG. 8B, the mask layer 810 is used as a mask to perform an etching process, so as to remove the inter layer 809 and the first dichroic layer 808 not covered by the mask layer 810, and leave the inter layer 809a and the first dichroic layer 808a on the first region 802.

Next, referring to FIG. 8C, a second dichroic layer 812 is formed on the substrate 800 to cover the mask layer 810 and the surface of the second region 804 of the substrate 800. The color of the second dichroic layer 812 is different from that of the first dichroic layer 808, and for example, is one selected from among a red film, a green film, or a blue film.

Then, referring to FIG. 8D, a lift-off process is performed to remove the mask layer 810 and the second dichroic layer 812 thereon, and leave the second dichroic layer 812a and an edge protrusion 812b on the second region 804. The lift-off process can be implemented with a wet removing process.

Afterwards, a mask layer 814 is formed on the second dichroic layer 812a on the second region 804, so as to expose the edge protrusion 812b. The mask layer 814 is, for example, an organic material layer or a buffer layer. The organic material layer is, for example, a patterned photoresist layer. The buffer layer is, for example, polymer material such as photoresist.

Next, referring to FIG. 8E, the edge protrusion 812b is etched away using the mask layer 814 and the inter layer 809a as a mask. Then, the mask layer 814 and the inter layer 809a are removed to expose the first dichroic layer 808a and the second dichroic layer 812a on the first region 802, the second region 804, and the third region 806. The mask layer 814 can be removed through a wet or a dry removing process. When the inter layer 809a is spin on glass, the wet etching process, for example, with hydrofluoric acid as the etching solution can be used to remove the inter layer.

In this embodiment, a single lift-off process is used first, and then the mask layers, the inter layer, and the etching process are used to form the second dichroic layer. The edge protrusion left after the lift-off process for forming the second dichroic layer in the second region can be completely removed with the inter layer and the mask layers formed subsequently through the etching process. Therefore, the finished color filter does not have the problem of edge protrusions.

### The Seventeenth Embodiment

FIGS. 9A-1 to 9E-1 are sectional views of the processes of a method of fabricating a tricolor filter according to the seventeenth embodiment of the present invention.

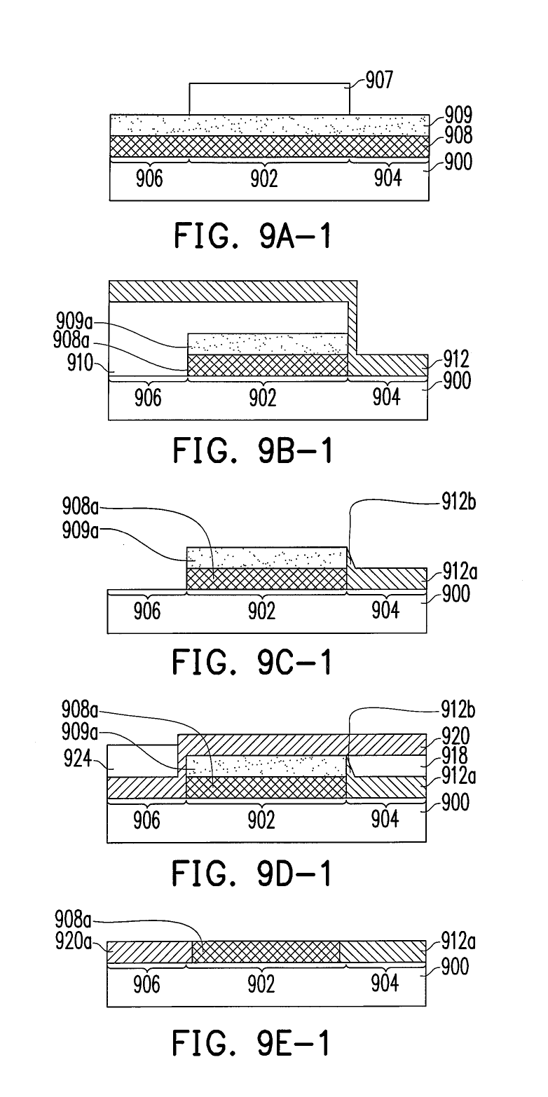

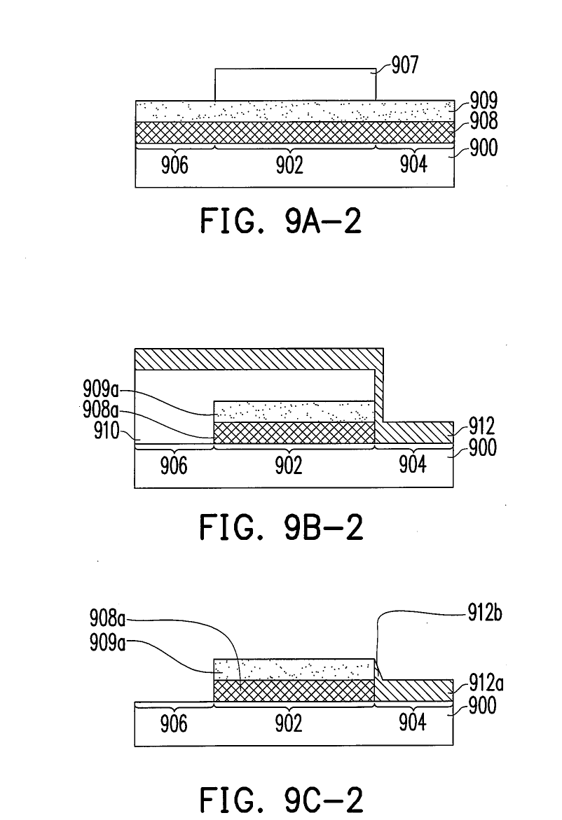

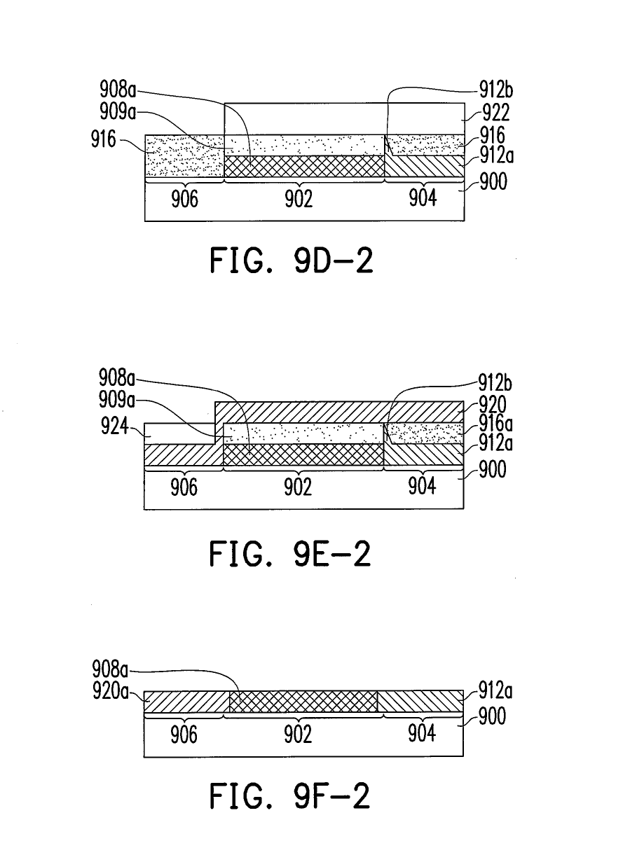

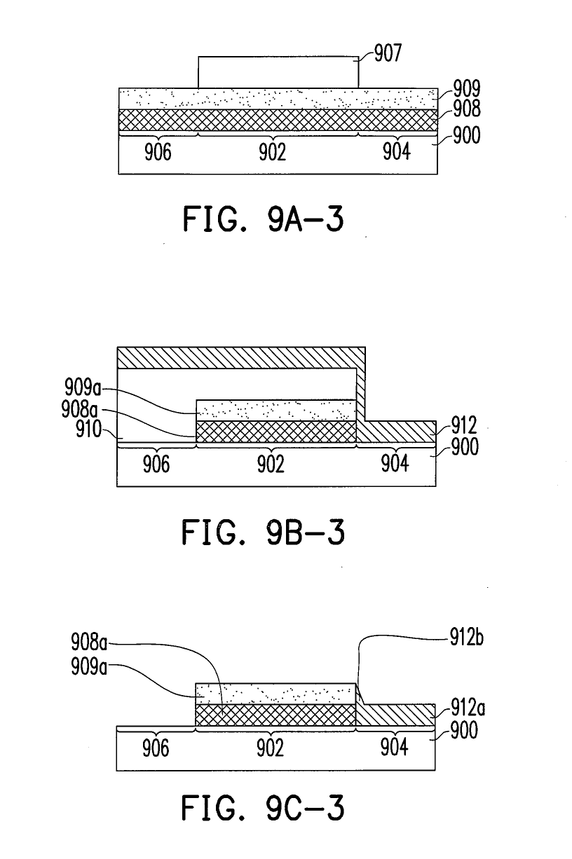

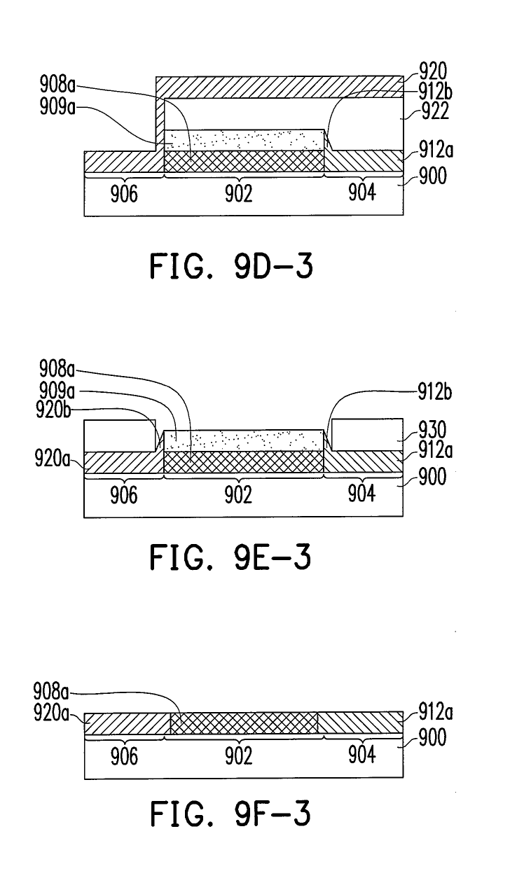

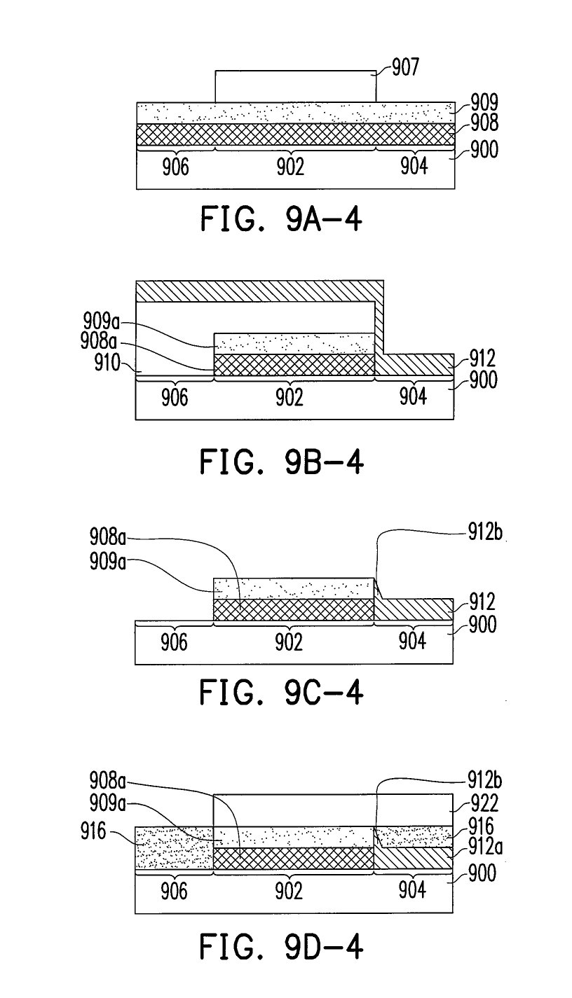

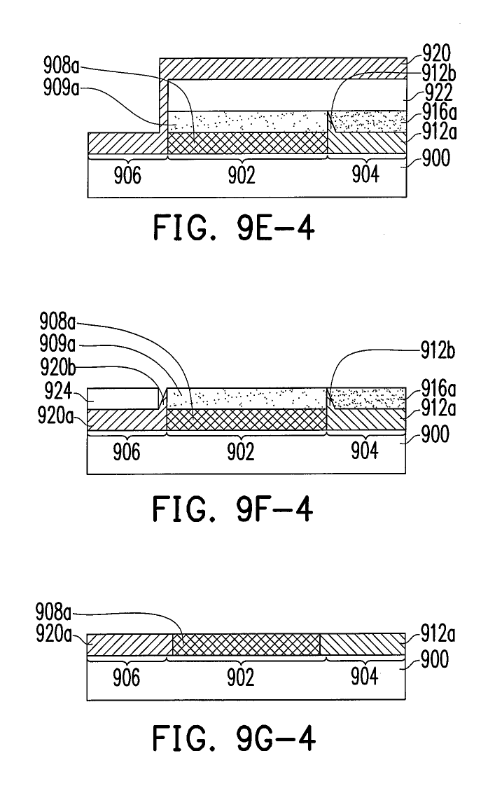

Referring to FIG. 9A-1, the color filter of this embodiment is fabricated on a substrate 900. For example, the substrate 900 is a silicon substrate including a first region 902, a second region 904, and a third region 906, and a conventional semiconductor element (not shown) has been formed on the substrate 900. Firstly, a first dichroic layer 908 and an inter layer 909 are formed on the substrate 900, and a mask layer 907 is formed over the first region 902 of the substrate 900. The first dichroic layer 908 is, for example, one selected from among a red film, a green film, or a blue film. The material of the inter layer 909 is, for example, an insulating material, such as silicon oxide or spin on glass. The mask layer 907 is, for example, a patterned photoresist layer.

Then, referring to FIG. 9B-1, the mask layer 907 is used as a mask to perform an etching process, so as to remove the inter layer 909 and the first dichroic layer 908 not covered by the mask layer 907, and leave the inter layer 909a and the first dichroic layer 908a on the first region 902.

Then, the mask layer 907 is removed, and then a mask layer 910 is formed on the first dichroic layer 908a on the first region 902 and the surface of the third region 908a of the substrate 900. The mask layer 910 is, for example, a patterned photoresist layer. Next, a second dichroic layer 912 is formed on the substrate 900 to cover the mask layer 910 and the surface of the second region 904 of the substrate 900. The color of the second dichroic layer 912 is different from that of the first dichroic layer 908a, and for example, is one selected from among a red film, a green film, or a blue film. In this embodiment, the second dichroic layer 912 is, for example, a green film for illustration.

Then, referring to FIG. 9C-1, a lift-off process is performed to remove the mask layer 910 and the second dichroic layer 912 thereon, and leave the second dichroic layer 912a and an edge protrusion 912b on the second region 904. The lift-off process can be implemented with a wet removing process.

Then, referring to FIG. 9D-1, a mask layer 918 is formed on the second dichroic layer 912a on the second region 904. In this embodiment, the mask layer 918 exposes the edge protrusion 912b. The mask layer 918 is, for example, an organic material layer or a buffer layer. The organic material layer is, for example, a patterned photoresist layer. The buffer layer is, for example, polymer material such as photoresist.

Next, a third dichroic layer 920 is formed on the substrate 900 to cover the mask layer 918, the inter layer 909a and the surface of the third region 906 of the substrate 900. The color of the third dichroic layer 920 is different from that of the first dichroic layer 908a and the second dichroic layer 912a, and for example, is one selected from among a red film, a green film, or a blue film. In this embodiment, the third dichroic layer 920 is, for example, a blue film for illustration.

Thereafter, a mask layer 924 is formed on the third dichroic layer 920 on the third region 906. The mask layer 924 is, for example, an organic material layer or a buffer layer. The organic material layer is, for example, a patterned photoresist layer. The buffer layer is, for example, polymer material such as photoresist.

Then, referring to FIG. 9E-1, the third dichroic layer 920 is etched back, so as to remove the third dichroic layer 920 on the mask layer 918 and the inter layer 909a and between the mask layer 924 and the inter layer 909a, etch away the edge protrusion 912b at the same time, and leave the third dichroic layer 920a on the third region 906 and the second dichroic layer 912a on the second region 904. The etch back process can be controlled through, for example, a time control method.

Next, the mask layers 918, 924 and the inter layer 909a are removed to expose the first dichroic layer 908a, the second dichroic layer 912a, and the third dichroic layer 920a on the first region 902, the second region 904, and the third region 906. When the materials of the mask layers 918 and 924 are organic materials, a wet or a dry removing process, e.g., a plasma ashing process can be used to remove both of the mask layers at the same time. When the inter layer 909a is spin on glass, the wet etching process, for example, with hydrofluoric acid as the etching solution can be used to remove the inter layer.

In this embodiment, a single lift-off process is used first, then an etching process is used, and the mask layers and the inter layer are used together, so as to form the second dichroic layer and the third dichroic layer. The edge protrusion left after the lift-off process for forming the second dichroic layer in the second region can be completely removed with the inter layer and the mask layers formed subsequently through the etching process. Therefore, the finished color filter does not have the problem of edge protrusions.

### The Eighteenth Embodiment

FIGS. 9A-2 to 9F-2 are sectional views of the processes of a method of fabricating a tricolor filter according to the eighteenth embodiment of the present invention.

Referring to FIG. 9A-2, the color filter of this embodiment is fabricated on a substrate 900. For example, the substrate 900 is a silicon substrate including a first region 902, a second region 904, and a third region 906, and a conventional semiconductor element (not shown) has been formed on the substrate 900. Firstly, a first dichroic layer 908 and an inter layer 909 are formed on the substrate 900, and a mask layer 907 is formed over the first region 902 of the substrate 900. The first dichroic layer 908 is, for example, one selected from among a red film, a green film, or a blue film. The material of the inter layer 909 is, for example, an insulating material, such as silicon oxide or spin on glass. The mask layer 907 is, for example, a patterned photoresist layer.

Then, referring to FIG. 9B-2, the mask layer 907 is used as a mask to perform an etching process, so as to remove the inter layer 909 and the first dichroic layer 908 not covered by the mask layer 907, and leave the inter layer 909a and the first dichroic layer 908a on the first region 902.

Then, the mask layer 907 is removed, and then a mask layer 910 is formed on the first dichroic layer 908a on the first region 902 and the surface of the third region 908a of the substrate 900. The mask layer 910 is, for example, a patterned photoresist layer. Next, a second dichroic layer 912 is formed on the substrate 900 to cover the mask layer 910 and the surface of the second region 904 of the substrate 900. The color of the second dichroic layer 912 is different from that of the first dichroic layer 908a, and for example, is one selected from among a red film, a green film, or a blue film. In this embodiment, the second dichroic layer 912 is, for example, a green film for illustration.

Then, referring to FIG. 9C-2, a lift-off process is performed to remove the mask layer 910 and the second dichroic layer 912 thereon, and leave the second dichroic layer 912a and an edge protrusion 912b on the second region 904. The lift-off process can be implemented with a wet removing process.

Then, referring to FIG. 9D-2, an inter layer 916 is formed on the substrate 900. The material of the inter layer 916 is, for example, an insulating material, such as silicon oxide or spin on glass (SOG). In this embodiment, the inter layer 916 exposes the edge protrusion 912b. Then, a mask layer 922 is formed over the first region 902 and the second region 904. The mask layer 922 is, for example, an organic material layer or a buffer layer. The organic material layer is, for example, a patterned photoresist layer. The buffer layer is, for example, polymer material such as photoresist.

Then, referring to FIG. 9E-2, an etching process is performed to remove the inter layer 916 not covered by the mask layer 922, and leave the inter layer 916a on the first dichroic layer 908a and the second dichroic layer 912a. The etching process can be a dry or a wet etching process.

Next, the mask layer 918 is removed, and a third dichroic layer 920 is formed on the substrate 900 to cover the inter layers 916a and 909a and the surface of the third region 906 of the substrate 900. The color of the third dichroic layer 920 is different from that of the first dichroic layer 908a and the second dichroic layer 912a, and for example, is one selected from among a red film, a green film, or a blue film. In this embodiment, the third dichroic layer 920 is, for example, a blue film for illustration.

Thereafter, a mask layer 924 is formed on the third dichroic layer 920 on the third region 906. The mask layer 924 is, for example, an organic material layer or a buffer layer. The organic material layer is, for example, a patterned photoresist layer. The buffer layer is, for example, polymer material such as photoresist.

Then, referring to FIG. 9F-2, the third dichroic layer 920 is etched back, so as to remove the third dichroic layer 920 over the inter layers 916a and 909a and between the mask layer 924 and the inter layer 909a, etch away the edge protrusion 912b at the same time, and leave the third dichroic layer 920a on the third region 906 and the second dichroic layer 912a on the second region. The etch back process can be controlled through, for example, a time control method.

Next, the mask layer 924 and the inter layers 909a and 916a are removed to expose the first dichroic layer 908a, the second dichroic layer 912a, and the third dichroic layer 920a on the first region 902, the second region 904, and the third region 906. When the material of the mask layer 924 is an organic material, a wet or a dry removing process, e.g., a plasma ashing process can be used to remove the mask layer. When the inter layers 909a and 916a are spin on glass, the wet etching process, for example, with hydrofluoric acid as the etching solution can be used to remove the inter layer. The mask layer 924 can be removed through a wet or a dry removing process.

The third dichroic layer of this embodiment is formed on the inter layer instead of the photoresist layer. Therefore, it is prevented that the photoresist layer contaminates the deposition chamber during the process of depositing the second dichroic layer. In this embodiment, a single lift-off process is used first, then an etch back process is used, and the mask layer and the inter layers are used together, so as to form the second dichroic layer and the third dichroic layer. The edge protrusion left after the lift-off process for forming the second dichroic layer in the second region can be completely removed with the inter layer and the mask layers formed subsequently through the etch back process. Therefore, the finished color filter does not have the problem of edge protrusions.

### The Nineteenth Embodiment

FIGS. 9A-3 to 9F-3 are sectional views of the processes of a method of fabricating a tricolor filter according to the nineteenth embodiment of the present invention.

Referring to FIG. 9A-3, the color filter of this embodiment is fabricated on a substrate 900. For example, the substrate 900 is a silicon substrate including a first region 902, a second region 904, and a third region 906, and a conventional semiconductor element (not shown) has been formed on the substrate 900. Firstly, a first dichroic layer 908 and an inter layer 909 are formed on the substrate 900, and a mask layer 907 is formed over the first region 902 of the substrate 900. The first dichroic layer 908 is, for example, one selected from among a red film, a green film, or a blue film. The material of the inter layer 909 is, for example, an insulating material, such as silicon oxide or spin on glass. The mask layer 907 is, for example, a patterned photoresist layer.

Then, referring to FIG. 9B-3, the mask layer 907 is used as a mask to perform an etching process, so as to remove the inter layer 909 and the first dichroic layer 908 not covered by the mask layer 907, and leave the inter layer 909a and the first dichroic layer 908a on the first region 902.

Then, the mask layer 907 is removed, and then a mask layer 910 is formed on the first dichroic layer 908a on the first region 902 and the surface of the third region 908a of the substrate 900. The mask layer 910 is, for example, a patterned photoresist layer. Next, a second dichroic layer 912 is formed on the substrate 900 to cover the mask layer 910 and the surface of the second region 904 of the substrate 900. The color of the second dichroic layer 912 is different from that of the first dichroic layer 908a, and for example, is one selected from among a red film, a green film, or a blue film. In this embodiment, the second dichroic layer 912 is, for example, a green film for illustration.

Then, referring to FIG. 9C-3, a lift-off process is performed to remove the mask layer 910 and the second dichroic layer 912 thereon, and leave the second dichroic layer 912a and an edge protrusion 912b on the second region 904. The lift-off process can be implemented with a wet removing process.

Thereafter, referring to FIG. 9D-3, another mask layer 922 is formed on the first dichroic layer 908a and the second dichroic layer 912a on the first region 902 and the second region 904. The mask layer 922 is, for example, a patterned photoresist layer. Next, a third dichroic layer 920 is formed on the substrate 900 to cover the mask layer 922 and the surface of the third region 906 of the substrate 900. The color of the third dichroic layer 920 is different from that of the first dichroic layer 908a and the second dichroic layer 912a, and for example, is one selected from among a red film, a green film, or a blue film. In this embodiment, the third dichroic layer 920 is, for example, a blue film for illustration.

Then, referring to FIG. 9E-3, a lift-off process is performed to remove the mask layer 922 and the third dichroic layer 920 thereon, and leave the third dichroic layer 920a on the third region 906 and an edge protrusion 920b. The lift-off process can be implemented with a wet removing process.

Then, a mask layer 930 is formed on the second, and the third dichroic layers 908a and 912a to expose the edge protrusions 920b and 912b. The mask layer 930 is, for example, an organic material layer or a buffer layer. The organic material layer is, for example, a patterned photoresist layer. The buffer layer is, for example, polymer material such as photoresist.

Next, referring to FIG. 9F-3, the edge protrusion 920b is etched away using the mask layer 930 as a mask. Then, the mask layer 930 is removed to expose the first dichroic layer 908a, the second dichroic layer 912a, and the third dichroic layer 920a on the first region 902, the second region 904, and the third region 906. The mask layer 930 can be removed through a wet or a dry removing process.

In this embodiment, a double lift-off process is used, and the mask layers, the inter layer, and the etching process are used, so as to form the second dichroic layer and the third dichroic layer. The first and the second edge protrusions left after the lift-off process for forming the second dichroic layer in the second region and after the lift-off process for forming the third dichroic layer in the third region respectively can be completely removed with the inter layer and the mask layers formed subsequently through the etching process. Therefore, the finished color filter does not have the problem of edge protrusions.

### The Twentieth Embodiment

FIGS. 9A-4 to 9G-4 are sectional views of the processes of a method of fabricating a tricolor filter according to the twentieth embodiment of the present invention.

Referring to FIG. 9A-4, the color filter of this embodiment is fabricated on a substrate 900. For example, the substrate 900 is a silicon substrate including a first region 902, a second region 904, and a third region 906, and a conventional semiconductor element (not shown) has been formed on the substrate 900. Firstly, a first dichroic layer 908 and an inter layer 909 are formed on the substrate 900, and a mask layer 907 is formed over the first region 902 of the substrate 900. The first dichroic layer 908 is, for example, one selected from among a red film, a green film, or a blue film. The material of the inter layer 909 is, for example, an insulating material, such as silicon oxide or spin on glass. The mask layer 907 is, for example, a patterned photoresist layer.

Then, referring to FIG. 9B-4, the mask layer 907 is used as a mask to perform an etching process, so as to remove the inter layer 909 and the first dichroic layer 908 not covered by the mask layer 907, and leave the inter layer 909a and the first dichroic layer 908a on the first region 902.

Then, the mask layer 907 is removed, and then a mask layer 910 is formed on the first dichroic layer 908a on the first region 902 and the surface of the third region 908a of the substrate 900. The mask layer 910 is, for example, a patterned photoresist layer. Next, a second dichroic layer 912 is formed on the substrate 900 to cover the mask layer 910 and the surface of the second region 904 of the substrate 900. The color of the second dichroic layer 912 is different from that of the first dichroic layer 908a, and for example, is one selected from among a red film, a green film, or a blue film. In this embodiment, the second dichroic layer 912 is, for example, a green film for illustration.

Then, referring to FIG. 9C-4, a lift-off process is performed to remove the mask layer 910 and the second dichroic layer 912 thereon, and leave the second dichroic layer 912a and an edge protrusion 912b on the second region 904. The lift-off process can be implemented with a wet removing process.

Then, referring to FIG. 9D-4, an inter layer 916 is formed on the substrate 900, and a mask layer 922 is formed on the inter layer 916 of the first region 902 and the second region 904. The material of the inter layer 916 is, for example, an insulating material, such as silicon oxide or spin on glass (SOG). The mask layer 922 is, for example, a patterned photoresist layer.

Then, referring to FIG. 9E-4, an etching process is performed to remove the inter layer 916 not covered by the mask layer 918, and leave the inter layer 916a on the first dichroic layer 908a and the second dichroic layer 912a. The etching process can be a dry or a wet etching process.

Next, a third dichroic layer 920 is formed on the substrate 900 to cover the mask layer 922 and the surface of the third region 906 of the substrate 900. The color of the third dichroic layer 920 is different from that of the first dichroic layer 908a and the second dichroic layer 912a, and for example, is one selected from among a red film, a green film, or a blue film. In this embodiment, the third dichroic layer 920 is, for example, a blue film for illustration.

Then, referring to FIG. 9F-4, a lift-off process is performed to remove the mask layer 918 and the third dichroic layer 920 thereon, and leave the third dichroic layer 920a on the third region 906 and an edge protrusion 920b. The lift-off process can be implemented with a wet removing process.

Afterwards, a mask layer 924 is formed on the third dichroic layer 920 on the third region 906, so as to expose the edge protrusions 920b, 912b and the inter layers 909a, 916a. The mask layer 924 is, for example, an organic material layer or a buffer layer. The organic material layer is, for example, a patterned photoresist layer. The buffer layer is, for example, polymer material such as photoresist.

Next, referring to FIG. 9G-4, the edge protrusions 912b and 920b are etched away using the mask layer 924 and the inter layers 909a and 916a as a mask. Then, the mask layer 924 and the inter layers 909a and 916a are removed to expose the first dichroic layer 908a, the second dichroic layer 912a, and the third dichroic layer 920a on the first region 902, the second region 904, and the third region 906. When the material of the mask layer 924 is an organic material, a wet or a dry removing process, e.g., a plasma ashing process can be used to remove the mask layer. When the inter layers 909a and 916a are spin on glass, the wet etching process, for example, with hydrofluoric acid as the etching solution can be used to remove the inter layers.

In this embodiment, a double etch back process is used, and a plurality of inter layers, mask layers, and the etching process are used, so as to form the second dichroic layer and the third dichroic layer. The first and the second edge protrusions left after the lift-off process for forming the second dichroic layer in the second region and after the lift-off process for forming the third dichroic layer in the third region respectively can be completely removed with the inter layer and the mask layers formed subsequently through the etching process. Therefore, the finished color filter does not have the problem of edge protrusions.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a color filter, comprising:
providing a substrate having a first region and a second region;
forming a first dichroic layer and a first mask layer on the first region sequentially;
forming a second dichroic layer on the substrate to cover the first mask layer and the surface of the second region of the substrate;
forming a second mask layer on the second dichroic layer of the second region;
etching the second dichroic layer on the first region and between the first mask layer and the second mask layer; and
removing the first mask layer and the second mask layer.

2. The method of fabricating a color filter as claimed in claim 1, wherein the first mask layer comprises a photoresist layer.

3. The method of fabricating a color filter as claimed in claim 1, wherein the second mask layer comprises an organic material layer or a buffer layer.

4. The method of fabricating a color filter as claimed in claim 1, wherein the first dichroic layer and the second dichroic layer are stacked layers selected from a group consisting of TiO₂, Ta₂O₅, SiO₂, RuₓO_{y}, ZnS, and MgF₂.

5. The method of fabricating a color filter as claimed in claim 1, wherein the substrate further comprises a third region, such that the first region is located between the second region and the third region, the method further comprising:
forming a third mask layer on the first dichroic layer and the second dichroic layer;
forming a third dichroic layer on the substrate to cover the third mask layer and the surface of the third region of the substrate;
forming a fourth mask layer on the third dichroic layer on the third region;
etching back the third dichoric layer, so as to remove the third dichroic layer on the third mask layer and between the third mask layer and the fourth mask layer; and
removing the third and the fourth mask layers.

6. The method of fabricating a color filter as claimed in claim 5, wherein the third mask layer comprises a photoresist layer.

7. The method of fabricating a color filter as claimed in claim 5, wherein the fourth mask layer comprises an organic material layer or a buffer layer.

8. The method of fabricating a color filter as claimed in claim 5, wherein the third dichroic layer is a stacked layer selected from a group consisting of TiO₂, Ta₂O₅, SiO₂, RuₓO_{y}, ZnS, and MgF₂.

9. The method of fabricating a color filter as claimed in claim 1, wherein the substrate further comprises a third region, such that the first region is located between the second region and the third region, the method further comprising:
forming an inter layer on the first dichroic layer and the second dichroic layer;
forming a third dichroic layer on the substrate to cover the inter layer and the surface of the third region of the substrate;
forming a third mask layer on the third dichroic layer on the third region;
etching back the third dichoric layer, so as to remove the third dichroic layer on the inter layer and between the third mask layer and the inter layer; and
removing the third mask layer and the inter layer.

10. The method of fabricating a color filter as claimed in claim 9, wherein the third mask layer comprises an organic material layer or a buffer layer.

11. The method of fabricating a color filter as claimed in claim 9, wherein a material of the inter layer comprises silicon oxide or spin on glass.

12. The method of fabricating a color filter as claimed in claim 9, wherein the third dichroic layer is a stacked layer selected from a group consisting of TiO₂, Ta₂O₅, SiO₂, RuₓO_{y}, ZnS, and MgF₂.

13. The method of fabricating a color filter as claimed in claim 1, wherein the substrate further comprises a third region, such that the first region is located between the second region and the third region, the method further comprising:
forming a third mask layer on the first dichroic layer and the second dichroic layer;
forming a third dichroic layer on the substrate to cover the third mask layer and the surface of the third region of the substrate;
performing a lift-off process to remove the third mask layer and the third dichroic layer thereon, and leave the third dichroic layer and an edge protrusion on the third region;
forming a fourth mask layer on the first, the second, and the third dichroic layers to expose the edge protrusion;
using the fourth mask layer as a mask, etching away the edge protrusion; and
removing the fourth mask layer.

14. The method of fabricating a color filter as claimed in claim 13, wherein the third mask layer comprises a photoresist layer.

15. The method of fabricating a color filter as claimed in claim 13, wherein the fourth mask layer comprises an organic material layer or a buffer layer.

16. The method of fabricating a color filter as claimed in claim 13, wherein the third dichroic layer is a stacked layer selected from a group consisting of TiO₂, Ta₂O₅, SiO₂, RuₓO_{y}, ZnS, and MgF₂.

17. The method of fabricating a color filter as claimed in claim 1, wherein the substrate further comprises a third region, such that the first region is located between the second region and the third region, the method further comprising:
forming an inter layer and a third mask layer on the first dichroic layer and the second dichroic layer sequentially;
forming a third dichroic layer on the substrate to cover the third mask layer and the surface of the third region of the substrate;
performing a lift-off process to remove the third mask layer and the third dichroic layer thereon, and leave the third dichroic layer on the third region and an edge protrusion;
forming a fourth mask layer on the third dichroic layer to expose the edge protrusion;
etching away the edge protrusion using the fourth mask layer and the inter layer as a mask; and
removing the fourth mask layer and the inter layer.

18. The method of fabricating a color filter as claimed in claim 17, wherein the third mask layer comprises a photoresist layer.

19. The method of fabricating a color filter as claimed in claim 17, wherein the fourth mask layer comprises an organic material layer or a buffer layer.

20. The method of fabricating a color filter as claimed in claim 17, wherein a material of the inter layer comprises silicon oxide or spin on glass.

21. The method of fabricating a color filter as claimed in claim 17, wherein the third dichroic layer is a stacked layer selected from a group consisting of TiO₂, Ta₂O₅, SiO₂, RuₓO_{y}, ZnS, and MgF₂.

22. A method of fabricating a color filter, comprising:
providing a substrate having a first region and a second region;
forming a first dichroic layer and a first inter layer on the first region sequentially;
forming a second dichroic layer on the substrate;
forming a first mask layer on the second dichroic layer on the second region;
using the first mask layer as an etching mask, etching the second dichroic layer on the first region and between the first inter layer and the first mask layer; and
removing the first inter layer and the first mask layer.

23. The method of fabricating a color filter as claimed in claim 22, wherein the first inter layer comprises silicon oxide or spin on glass.

24. The method of fabricating a color filter as claimed in claim 22, wherein the first mask layer comprises an organic material layer or a buffer layer.

25. The method of fabricating a color filter as claimed in claim 22, wherein the first dichroic layer and the second dichroic layer are stacked layers selected from a group consisting of TiO₂, Ta₂O₅, SiO₂, RuₓO_{y}, ZnS, and MgF₂.

26. The method of fabricating a color filter as claimed in claim 22, wherein the substrate further comprises a third region, such that the first region is located between the second region and the third region, the method further comprising:
forming a second mask layer on the first dichroic layer and the second dichroic layer;
forming a third dichroic layer on the substrate to cover the second mask layer and the surface of the third region of the substrate;
forming a third mask layer on the third dichroic layer on the third region;
etching back the third dichoric layer, so as to remove the third dichroic layer on the second mask layer and between the first inter layer and the third mask layer; and
removing the second and the third mask layers and the first inter layer.

27. The method of fabricating a color filter as claimed in claim 26, wherein the second mask layer comprises a photoresist layer.

28. The method of fabricating a color filter as claimed in claim 26, wherein the third mask layer comprises an organic material layer or a buffer layer.

29. The method of fabricating a color filter as claimed in claim 26, wherein the third dichroic layer is a stacked layer selected from a group consisting of TiO₂, Ta₂O₅, SiO₂, RuₓO_{y}, ZnS, and MgF₂.

30. The method of fabricating a color filter as claimed in claim 22, wherein the substrate further comprises a third region, such that the first region is located between the second region and the third region, the method further comprising:
forming a second inter layer on the second dichroic layer;
forming a third dichroic layer on the substrate to cover the first and the second inter layers and the surface of the third region of the substrate;
forming a second mask layer on the third dichroic layer on the third region;
etching back the third dichoric layer, so as to remove the third dichroic layer on the first and the second inter layers and between the second mask layer and the first inter layer; and
removing the second mask layer and the first and the second inter layers.

31. The method of fabricating a color filter as claimed in claim 30, wherein a material of the second inter layer comprises silicon oxide or spin on glass.

32. The method of fabricating a color filter as claimed in claim 30, wherein the second mask layer comprises an organic material layer or a buffer layer.

33. The method of fabricating a color filter as claimed in claim 30, wherein the third dichroic layer is a stacked layer selected from a group consisting of TiO₂, Ta₂O₅, SiO₂, RuₓO_{y}, ZnS, and MgF₂.

34. The method of fabricating a color filter as claimed in claim 22, wherein the substrate further comprises a third region, such that the first region is located between the second region and the third region, the method further comprising:
forming a second mask layer over the first region and the second region;
forming a third dichroic layer on the substrate to cover the second mask layer and the surface of the third region of the substrate;
performing a lift-off process to remove the second mask layer and the first dichroic layer thereon, and leave the third dichroic layer on the third region and an edge protrusion;
forming a third mask layer on the second dichroic layer and the third dichroic layer to expose the edge protrusion;
using the third mask layer and the first inter layer as a mask, etching away the edge protrusion; and
removing the third mask layer and the first inter layer.

35. The method of fabricating a color filter as claimed in claim 34, wherein the second mask layer comprises a photoresist layer.

36. The method of fabricating a color filter as claimed in claim 34, wherein the third mask layer comprises an organic material layer or a buffer layer.

37. The method of fabricating a color filter as claimed in claim 34, wherein the third dichroic layer is a stacked layer selected from a group consisting of TiO₂, Ta₂O₅, SiO₂, RuₓO_{y}, ZnS, and MgF₂.

38. The method of fabricating a color filter as claimed in claim 22, wherein the substrate further comprises a third region, such that the first region is located between the second region and the third region, the method further comprising:
forming a second inter layer on the second dichroic layer;
forming a second mask layer on the first inter layer and the second inter layer;
forming a third dichroic layer on the substrate to cover the second mask layer and the surface of the third region of the substrate;
performing a lift-off process to remove the second mask layer and the third dichroic layer thereon, and leave the third dichroic layer on the third region and an edge protrusion;
forming a third mask layer on the third dichroic layer to expose the edge protrusion;
using the third mask layer and the first and the second inter layers as a mask, etching away the edge protrusion; and
removing the third mask layer and the first and the second inter layers.

39. The method of fabricating a color filter as claimed in claim 38, wherein a material of the second inter layer comprises silicon oxide or spin on glass.

40. The method of fabricating a color filter as claimed in claim 38, wherein the second mask layer comprises a photoresist layer.

41. The method of fabricating a color filter as claimed in claim 38, wherein the third mask layer comprises an organic material layer or a buffer layer.

42. The method of fabricating a color filter as claimed in claim 38, wherein the third dichroic layer is a stacked layer selected from a group consisting of TiO₂, Ta₂O₅, SiO₂, RuₓO_{y}, ZnS, and MgF₂.

43. A method of fabricating a color filter, comprising:
providing a substrate having a first region and a second region;
forming a first dichroic layer and a first mask layer on the first region of the substrate sequentially;
forming a second dichroic layer on the substrate to cover the first mask layer and the surface of the second region of the substrate;
performing a first lift-off process to remove the first mask layer and the first dichroic layer thereon, and leave the second dichroic layer on the second region and an edge protrusion;
forming a second mask layer on the substrate to cover the second region;
etching the edge protrusion; and
removing the second mask layer.

44. The method of fabricating a color filter as claimed in claim 43, wherein the first mask layer comprises a photoresist layer.

45. The method of fabricating a color filter as claimed in claim 43, wherein the second mask layer comprises an organic material layer or a buffer layer.

46. The method of fabricating a color filter as claimed in claim 43, wherein the first and the second dichroic layers are stacked layers selected from a group consisting of TiO₂, Ta₂O₅, SiO₂, RuₓO_{y}, ZnS, and MgF₂.

47. The method of fabricating a color filter as claimed in claim 43, wherein the substrate further comprises a third region, such that the first region is located between the second region and the third region; after the first lift-off process is performed, the method further comprising:
forming the second mask layer on the substrate to cover the second dichroic layer on the second region and cover the first dichroic layer on the first region;
forming a third dichroic layer on the substrate to cover the second mask layer and the surface of the third region of the substrate;
forming a third mask layer on the third dichroic layer on the third region; and
etching back the third dichoric layer, so as to remove the third dichroic layer on the second mask layer and between the second mask layer and the third mask layer and remove the first edge protrusion at the same time; and
removing the second mask layer, and removing the third mask layer at the same time.

48. The method of fabricating a color filter as claimed in claim 47, wherein the second mask layer comprises a photoresist layer.

49. The method of fabricating a color filter as claimed in claim 47, wherein the third mask layer comprises an organic material layer or a buffer layer.

50. The method of fabricating a color filter as claimed in claim 47, wherein the third dichroic layer is a stacked layer selected from a group consisting of TiO₂, Ta₂O₅, SiO₂, RuₓO_{y}, ZnS, and MgF₂.

51. The method of fabricating a color filter as claimed in claim 43, wherein the substrate further comprises a third region, such that the first region is located between the second region and the third region, and the first mask layer further covers the surface of the third region of the substrate; after the first lift-off process is performed, the method further comprising:
forming an inter layer on the substrate;
forming the second mask layer on the substrate to cover the second region and the first region;
etching away the inter layer not covered by the second mask layer;
removing the second mask layer;
forming a third dichroic layer on the substrate to cover the inter layer and the surface of the third region of the substrate;
forming a third mask layer on the third dichroic layer on the third region;
etching back the third dichoric layer, so as to remove the third dichroic layer on the inter layer and between the third mask layer and the inter layer and remove the first edge protrusion; and
removing the third mask layer and the inter layer.

52. The method of fabricating a color filter as claimed in claim 51, wherein a material of the inter layer comprises silicon oxide or spin on glass.

53. The method of fabricating a color filter as claimed in claim 51, wherein the third mask layer comprises an organic material layer or a buffer layer.

54. The method of fabricating a color filter as claimed in claim 51, wherein the third dichroic layer is a stacked layer selected from a group consisting of TiO₂, Ta₂O₅, SiO₂, RuₓO_{y}, ZnS, and MgF₂.

55. The method of fabricating a color filter as claimed in claim 43, wherein the substrate further comprises a third region, such that the first region is located between the second region and the third region, and the first mask layer further covers the surface of the third region of the substrate; after the first lift-off process is performed, the method further comprising:
forming the second mask layer on the substrate to cover the second region and the first region;
forming a third dichroic layer on the substrate to cover the second mask layer and the surface of the third region of the substrate;
performing a second lift-off process to remove the second mask layer and the third dichroic layer thereon, and leave the third dichroic layer on the third region and a second edge protrusion;
forming a third mask layer on the first, the second, and the third dichroic layers to expose the first and the second edge protrusions;
using the third mask layer as a mask, etching away the first and the second edge protrusion; and
removing the third mask layer.

56. The method of fabricating a color filter as claimed in claim 55, wherein the second mask layer comprises a photoresist layer.

57. The method of fabricating a color filter as claimed in claim 55, wherein the third mask layer comprises an organic material layer or a buffer layer.

58. The method of fabricating a color filter as claimed in claim 55, wherein the third dichroic layer is a stacked layer selected from a group consisting of TiO₂, Ta₂O₅, SiO₂, RuₓO_{y}, ZnS, and MgF₂.

59. The method of fabricating a color filter as claimed in claim 43, wherein the substrate further comprises a third region, such that the first region is located between the second region and the third region, and the first mask layer further covers the surface of the third region of the substrate; after the first lift-off process is performed, the method further comprising:
forming an inter layer on the first dichroic layer and the second dichroic layer;
forming the second mask layer on the substrate to cover the second region and the first region;
forming a third dichroic layer on the substrate to cover the second mask layer and the surface of the third region of the substrate;
performing a second lift-off process to remove the second mask layer and the third dichroic layer thereon, and leave the third dichroic layer and a second edge protrusion on the third region;
forming a third mask layer on the third dichroic layer to expose the second edge protrusion;
using the third mask layer and the inter layer as a mask, etching away the first and the second edge protrusions; and
removing the third mask layer and the inter layer.

60. The method of fabricating a color filter as claimed in claim 59, wherein a material of the inter layer comprises silicon oxide or spin on glass.

61. The method of fabricating a color filter as claimed in claim 59, wherein the second mask layer comprises a photoresist layer.

62. The method of fabricating a color filter as claimed in claim 59, wherein the third mask layer comprises an organic material layer or a buffer layer.

63. The method of fabricating a color filter as claimed in claim 59, wherein the third dichroic layer is a stacked layer selected from a group consisting of TiO₂, Ta₂O₅, SiO₂, RuₓO_{y}, ZnS, and MgF₂.

64. A method of fabricating a color filter, comprising:
providing a substrate having a first region and a second region;
forming a first dichroic layer, a first inter layer, and a first mask layer on the first region of the substrate sequentially;
forming a second dichroic layer on the substrate;
performing a first lift-off process to remove the first mask layer and the first dichroic layer thereon, and leave the second dichroic layer on the second region and a first edge protrusion;
forming a second mask layer on the substrate to cover the second region; and
using the second mask layer and the first inter layer as a mask, etching away the first edge protrusion; and
removing the first inter layer and the second mask layer.

65. The method of fabricating a color filter as claimed in claim 64, wherein a material of the first inter layer comprises silicon oxide or spin on glass.

66. The method of fabricating a color filter as claimed in claim 64, wherein the first mask layer comprises a photoresist layer.

67. The method of fabricating a color filter as claimed in claim 64, wherein the second mask layer comprises an organic material layer or a buffer layer.

68. The method of fabricating a color filter as claimed in claim 64, wherein the first and the second dichroic layers are stacked layers selected from a group consisting of TiO₂, Ta₂O₅, SiO₂, RuₓO_{y}, ZnS, and MgF₂.

69. The method of fabricating a color filter as claimed in claim 64, wherein the substrate further comprises a third region, such that the first region is located between the second region and the third region, and the first mask layer further covers the surface of the third region of the substrate; after the second mask layer is formed, the method further comprising:
forming a third dichroic layer on the substrate to cover the second mask layer and the surface of the third region of the substrate;
forming a third mask layer on the third dichroic layer on the third region;
etching back the third dichoric layer, so as to remove the third dichroic layer on the second mask layer and between the first inter layer and the third mask layer and to remove the first edge protrusion; and
removing the second and the third mask layers and the first inter layer.

70. The method of fabricating a color filter as claimed in claim 69, wherein the mask layer comprises an organic material layer or a buffer layer.

71. The method of fabricating a color filter as claimed in claim 69, wherein the third dichroic layer is a stacked layer selected from a group consisting of TiO₂, Ta₂O₅, SiO₂, RuₓO_{y}, ZnS, and MgF₂.

72. The method of fabricating a color filter as claimed in claim 64, wherein the substrate further comprises a third region, such that the first region is located between the second region and the third region, and the first mask layer further covers the surface of the third region of the substrate; after the first lift-off process is performed, the method further comprising:
forming a second inter layer on the substrate;
forming a second mask layer on the substrate to cover the second region and the first region;
etching away the second inter layer not covered by the second mask layer;
removing the second mask layer;
forming a third dichroic layer on the substrate to cover the second inter layer and the surface of the third region of the substrate;
forming a third mask layer on the third dichroic layer on the third region;
etching back the third dichoric layer, so as to remove the third dichroic layer on the second inter layer and between the first inter layer and the third mask layer and to remove the first edge protrusion; and
removing the third mask layer and the first and the second inter layers.

73. The method of fabricating a color filter as claimed in claim 72, wherein a material of the second inter layer comprises silicon oxide or spin on glass.

74. The method of fabricating a color filter as claimed in claim 72, wherein the third mask layer comprises an organic material layer or a buffer layer.

75. The method of fabricating a color filter as claimed in claim 72, wherein the third dichroic layer is a stacked layer selected from a group consisting of TiO₂, Ta₂O₅, SiO₂, RuₓO_{y}, ZnS, and MgF₂.

76. The method of fabricating a color filter as claimed in claim 64, wherein the substrate further comprises a third region, such that the first region is located between the second region and the third region, and the first mask layer further covers the surface of the third region of the substrate; after the first lift-off process is performed, the method further comprising:
forming a second mask layer on the substrate to cover the second region and the first region;
forming a third dichroic layer on the substrate to cover the second mask layer and the surface of the third region of the substrate;
performing a second lift-off process to remove the second mask layer and the third dichroic layer thereon, and leave the third dichroic layer and a second edge protrusion on the third region;
forming a third mask layer on the second and the third regions to expose the first and the second edge protrusions;
using the third mask layer and the first inter layer as a mask, etching away the first and the second edge protrusions; and
removing the third mask layer and the first inter layer.

77. The method of fabricating a color filter as claimed in claim 76, wherein the second mask layer comprises a photoresist layer.

78. The method of fabricating a color filter as claimed in claim 76, wherein the third mask layer comprises an organic material layer or a buffer layer.

79. The method of fabricating a color filter as claimed in claim 76, wherein the third dichroic layer is a stacked layer selected from a group consisting of TiO₂, Ta₂O₅, SiO₂, RuₓO_{y}, ZnS, and MgF₂.

80. The method of fabricating a color filter as claimed in claim 64, wherein the substrate further comprises a third region, such that the first region is located between the second region and the third region, and the first mask layer further covers the surface of the third region of the substrate; after the first lift-off process is performed, the method further comprising:
forming a second inter layer on the second dichroic layer;
forming a second mask layer on the substrate to cover the second region and the first region;
forming a third dichroic layer on the substrate to cover the second mask layer and the surface of the third region of the substrate;
performing a second lift-off process to remove the second mask layer and the third dichroic layer thereon, and leave the third dichroic layer on the third region and a second edge protrusion;
forming a third mask layer on the third region to expose the second edge protrusion;
using the third mask layer and the first and the second inter layers as a mask, etching away the first and the second edge protrusions; and
removing the third mask layer and the first and the second inter layers.

81. The method of fabricating a color filter as claimed in claim 80, wherein a material of the second inter layer comprises silicon oxide or spin on glass.

82. The method of fabricating a color filter as claimed in claim 80, wherein the second mask layer comprises a photoresist layer.

83. The method of fabricating a color filter as claimed in claim 80, wherein the third mask layer comprises an organic material layer or a buffer layer.

84. The method of fabricating a color filter as claimed in claim 80, wherein the third dichroic layer is a stacked layer selected from a group consisting of TiO₂, Ta₂O₅, SiO₂, RuₓO_{y}, ZnS, and MgF₂.
